(19) United States
(12) Patent Application Publication
(10) Pub. No.: US 2022/0291593 A1
(43) Pub. Date: Sep. 15, 2022

(54) METHOD AND APPARATUS FOR LITHOGRAPHIC PROCESS PERFORMANCE DETERMINATION

(71) Applicant: ASML NETHERLANDS B.V., Veldhoven (NL)

(72) Inventors: Roy WERKMAN, Eindhoven (NL); Pui Leng LAM, Veldhoven (NL); Blandine Marie Andree Richit MINGHETTI, Meylan (FR); Vahid BASTANI, Eindhoven (NL); Mohamadrezh HAJIAHMADI, Rotterdam (NL); Lydia Marianna VERGAIJ-HUIZER, Eindhoven (NL); Frans Reinier SPIERING, Amherm (NL)

(21) Appl. No.: 17/639,364

(22) PCT Filed: Aug. 5, 2020
(86) PCT No.: PCT/EP2020/071954

§ 371 Date: Mar. 1, 2022

(30) Foreign Application Priority Data
Dec. 19, 2016 (EP) 19217902.6
Sep. 4, 2019 (EP) 19195265.4
Sep. 23, 2019 (EP) 19198917.7
Feb. 14, 2020 (EP) 20157333.4
Apr. 14, 2020 (EP) 20169297.7

(51) Int. Cl. G03F 7/20; G03F 1/42

(52) U.S. Cl. CPC G03F 7/70475; G03F 1/42

(57) ABSTRACT

A method for characterizing a patterning process, the method including obtaining a plurality of values of stitching errors made along one or more boundaries between at least two patterned adjacent fields or sub-fields on a substrate; and fitting, using a hardware computer system, a distortion model to the plurality of values to obtain a fingerprint representing deformation of a field or sub-field out of the at least two patterned adjacent fields or sub-fields.

### CROSS-REFERENCE TO RELATED APPLICATOINS

This application claims priority of EP application 19195265.4 which was filed on Sep. 4, 2019, EP application 19198917.7 which was filed on Sep. 23, 2019, EP application 19217902.6 which was filed on Dec. 19, 2019, EP application 20157333.4 which was filed on Feb. 14, 2020, and EP application 20169297.7 which was filed on Apr. 14, 2020 which are incorporated herein in its entirety by reference.

### FIELD

The present invention relates apparatuses and methods for determining performance of a lithographic patterning process. In particular, it relates to determination of a performance of a lithographic patterning process based on characteristics of a boundary between first and second regions.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

Patterning of a layer on a substrate may comprise a multiple steps. For example, a patterning device, such as a mask, may not be big enough to pattern a substrate in one position. In some cases, the pattern to be exposed may fit into a single mask. The single mask may then be moved across the substrate, to expose the same pattern multiple times onto the same substrate. In other cases, the pattern to be exposed onto the substrate, for example a pattern forming a device, may be too big to fit on a single mask. Several masks, each comprising a different portion of the pattern to be exposed, may be moved across the substrate in multiple independent steps. The multiple masks be moved across regions of a substrate, to pattern different portions of the pattern sequentially. This breaking up of a pattern across different regions on a substrate may give rise to positioning errors of the exposed portions of the pattern on the substrate, relative to each other. An exposed pattern may comprise for example alignment and/or magnification errors. Due to the small dimensions of patterned features, high precision and accuracy may be required in positioning different patterned regions relative to each other. Errors in the relative positions may be referred to as stitching errors. Stitching errors may affect the quality of exposed pattern on a substrate, and the resulting yield of the patterning process. It is therefore desirable to provide methods and apparatuses to reduce stitching errors and their negative effects on lithographic patterning processes.

### SUMMARY

According to a first aspect of the disclosure, there is provided an apparatus for determining a performance of a lithographic patterning process, the apparatus comprising one or more processors configured to receive an image of a portion of a substrate, the portion of the substrate comprising a first region comprising first features associated with a first lithographic exposure of the substrate at a first time, and a second region comprising second features associated with a second lithographic exposure of the substrate at a second time, wherein the first and second regions do not overlap. The one or more processors are further configured to determine the performance of the lithographic patterning process based on one or more feature characteristics of the first and/or second exposed features associated with a boundary between the first region and the second region.

Optionally, the boundary may comprises a portion of an outer border of the first region and a portion of an outer border of the second region.

Optionally, the first features and the second features may comprise at least one of product features, and dummy features having one or more dimensions the same as the product features.

Optionally, the first features and the second features may form a single feature extending along at least part of the first region and at least part of the second region.

Optionally, the one or more feature characteristics may comprise a distance metric comprising a distance between one or more axes of symmetry of the first features and one or more axes of symmetry of the second features, and/or a physical distance between the first features and the second features.

Optionally, the one or more feature characteristics may comprise a narrowing or a thickening of the single feature at or proximal to the boundary.

Optionally, the first features and the second features may form part of a patterned layer of photoresist or a layer of material after being patterned by an etching process.

Optionally, determining the performance may comprise analysing the image to determine one or more feature characteristics of the first and/or second features associated with the boundary between the first region and the second region.

Optionally, determining the performance may comprise performing a comparison of the first and/or second features of the image to a standard for the first and/or second features.

Optionally, determining the performance may further comprises determining a performance of one or more lithographic patterning process characteristics, based on the determined one or more feature characteristics.

Optionally, the one or more feature characteristics may comprise a spatial dimension of the first and/or second features.

Optionally, the one or more process characteristics may comprise one or more of magnification, translation, and/or a higher order deformation error associated with the patterning of the first region and/or the second region.

Optionally, the performance of the one or more process characteristics may be determined at least in part using a model taking as input at least one of the one or more feature characteristics.

Optionally, the model may comprise a machine learning model.

Optionally, the model may comprise a neural network.

Optionally, the model may comprise vision technology.

Optionally, the model may be configured to be trained on a training set of images of a portion of the substrate comprising first and second features, wherein the first and/or second features of the training set images have one or more known feature characteristics linked to a known performance of the lithographic patterning process.

Optionally, each training set image may comprise a portion of a training substrate comprising first features associated with a first lithographic exposure of the training substrate at a first time, and second features associated with a second lithographic exposure of the training substrate at a second time.

Optionally, the known feature characteristics and performance of the lithographic patterning process may be at least partially based on one or more measurements of one or more feature characteristics of the first and/or second features.

Optionally, the known performance of the lithographic patterning process may comprise a known stitching error.

Optionally, determining the performance of the lithographic patterning process may comprise determining a pre-processed image obtained by removing noise from the image, and identifying the one or more feature characteristics from the pre-processed image.

Optionally, determining the pre-processed image may comprise determining a gradient magnitude of the image.

Optionally, determining the pre-processed image may comprise determining a binary image based on the image.

Optionally, determining the pre-processed image may comprise detecting the one or more line features in the image and/or the binary image, and rotating the image and/or the binary image such that at least one of the one or more line features is substantially parallel or substantially perpendicular to the boundary between the first region and the second region.

Optionally, identifying the one or more feature characteristics from the pre-processed image may comprise applying a Fourier transform to a plurality of portions of the pre-processed image for quantifying a stitching quality at the boundary between the first region and the second region.

Optionally, identifying the one or more feature characteristics may further comprise determining a duty cycle for the plurality of Fourier-transformed portions, and determining the one or more feature characteristics based on the duty cycle for the plurality of portions.

Optionally, identifying the one or more feature characteristics may further comprise determining a phase for the plurality of Fourier-transformed portions, and determining one or more feature characteristics based on the phase for the plurality of portions.

Optionally, the plurality of portions may comprise a plurality of pixel rows, wherein the rows may be aligned to the boundary between the first region and the second region.

Optionally, determining the performance of the lithographic patterning process may comprise determining a first binary image based on the image, determining a second binary image based on the binary gradient of the image, and identifying the one or more feature characteristics based on a combination of the first binary image and the second binary image.

Optionally, the one or more feature characteristics may comprise overlay.

Optionally, identifying the one or more feature characteristics may use a regression model and/or a lookup table.

Optionally, determining a performance of the lithographic patterning process may further comprise determining a metric for a stitching quality at the boundary between the first region and the second region.

Optionally, the metric may represent at least one of a flatness of the stitching around the boundary between the first region and the second region, and the skewness of the stitching around the boundary between the first region and the second region.

Optionally, the first region and the second region may form part of a same device on the substrate.

Optionally, the first region may be a first field exposed on the substrate, and the second region may be a second field exposed on the substrate. The boundary may comprise a portion of a border of the first field and a border of the second field.

Optionally, determining the performance may comprises determining a stitching error between the first field and the second field.

Optionally, the received image may comprise the substrate in between exposure of subsequent layers on the substrate.

Optionally, the received image may comprise a boundary between the first and second regions extending in at least one direction.

Optionally, the processor may be configured to receive a plurality of images, and determine the quality of the patterning process based on the plurality of images.

Optionally, the plurality of images comprise a first image comprising a boundary between the first and second regions in a first direction, and a second image comprising a boundary between the first region and a further region in a second direction. The first direction and the second direction may be not parallel to each other.

Optionally, the first direction and the second direction may be substantially perpendicular to each other.

Optionally, the one or more processors may be further configured to determine a performance of one or more process characteristics for the first image, and to determine one or more process characteristics for the second image. The one or more processors may be further configured to combine the one or more process characteristics of the first and second images to determine a performance of the patterning process.

Optionally, the plurality of images may depict a plurality of separate positions on the substrate.

Optionally, one or more process characteristics may be determined for the separate positions on the substrate.

Optionally, the one or more processors may be further configured to determine one or more corrections to the patterning process based on the performance of the lithographic patterning process.

Optionally, the one or more processors may be further configured to update the lithographic patterning process with the one or more corrections.

Optionally, updating the lithographic patterning process may comprise updating at least one of one or more exposure settings of a lithographic apparatus, and a reticle design.

Optionally, the lithographic patterning process may be configured to pattern a substrate using a reticle and electromagnetic radiation.

Optionally, the one or more processors may be further configured to control a metrology apparatus to obtain the image.

Optionally, controlling a metrology apparatus to obtain the image may comprise guiding the metrology apparatus is based on previously determined one or more feature characteristics.

Optionally, the metrology apparatus may comprise an electron beam imager.

According to another aspect of the disclosure, there is provided a method for determining a performance of a lithographic patterning process. The method comprises receiving an image of a portion of a substrate, the portion of the substrate comprising a first region comprising first features associated with a first lithographic exposure of the substrate at a first time, and a second region comprising second features associated with a second lithographic exposure of the substrate at a second time, wherein the first and second regions do not overlap. The method further comprises determining the performance of the lithographic patterning process based on one or more feature characteristics of the first and/or second exposed features associated with a boundary between the first region and the second region.

Optionally the boundary comprises a portion of an outer border of the first region and a portion of an outer border of the second region.

Optionally, the first features and the second features may comprise at least one of product features, and dummy features having one or more dimensions the same as the product features.

Optionally, the first features and the second features may form a single feature extending along at least part of the first region and at least part of the second region.

Optionally, the one or more feature characteristics may comprise a distance metric comprising a distance between one or more axes of symmetry of the first features and one or more axes of symmetry of the second features, and/or a physical distance between the first features and the second features.

Optionally, the one or more feature characteristics may comprise a narrowing or a thickening of the single feature at or proximal to the boundary.

Optionally, the first features and the second features may form part of a patterned layer of photoresist or a layer of material after being patterned by an etching process.

Optionally, determining the performance may comprise analysing the image to determine one or more feature characteristics of the first and/or second features associated with the boundary between the first region and the second region.

Optionally, determining the performance may comprise performing a comparison of the first and/or second features of the image to a standard for the first and/or second features.

Optionally, determining the performance may further comprise determining a performance of one or more lithographic patterning process characteristics, based on the determined one or more feature characteristics.

Optionally, the one or more feature characteristics may comprise a spatial dimension of the first and/or second features.

Optionally, the one or more process characteristics may comprise one or more of magnification, translation, and/or a higher order deformation error associated with the patterning of the first region and/or the second region.

Optionally, the performance of the one or more process characteristics may be determined at least in part using a model taking as input at least one of the one or more feature characteristics.

Optionally, the model may comprise a machine learning model.

Optionally, the model may comprise a neural network.

Optionally, the model may comprise vision technology.

Optionally, the first region and the second region may form part of a same device on the substrate.

Optionally, the first region may be a first field exposed on the substrate, the second region may be a second field exposed on the substrate. The boundary may comprises a portion of a border of the first field and a border of the second field.

Optionally, determining the performance may comprise determining a stitching error between the first field and the second field.

Optionally, the received image may comprise the substrate in between exposure of subsequent layers on the substrate.

Optionally, the received image may comprise a boundary between the first and second regions extending in at least one direction.

Optionally, the method may further comprise receiving a plurality of images, and determining the quality of the patterning process based on the plurality of images.

Optionally, the plurality of images may comprise a first image comprising a boundary between the first and second regions in a first direction, and a second image comprising a boundary between the first region and a further region in a second direction. The first direction and the second direction may be not parallel to each other.

Optionally, the first direction and the second direction may be substantially perpendicular to each other.

Optionally, the method may further comprise determining a performance of one or more process characteristics for the first image, and determining one or more process characteristics for the second image. The method may further comprise combining the one or more process characteristics of the first and second images to determine a performance of the patterning process.

Optionally the plurality of images may depict a plurality of separate positions on the substrate.

Optionally, one or more process characteristics may be determined for the separate positions on the substrate.

Optionally, the method may further comprise determining one or more corrections to the patterning process based on the performance of the lithographic patterning process.

Optionally, the method may further comprise updating the lithographic patterning process with the one or more corrections.

Optionally, updating the lithographic patterning process may comprise updating at least one of one or more exposure settings of a lithographic apparatus, and a reticle design.

Optionally, the lithographic patterning process may be configured to pattern a substrate using a reticle and electromagnetic radiation.

Optionally, the method may further comprise controlling a metrology apparatus to obtain the image.

Optionally, controlling a metrology apparatus to obtain the image comprises guiding the metrology apparatus may be based on previously determined one or more feature characteristics.

Optionally, the metrology apparatus may comprise an electron beam imager.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 depicts a flow diagram of steps in a method of determining a performance of a lithographic patterning process;

FIG. 5 depicts a schematic representation of a portion of a substrate comprising first and second regions with first and second features;

FIG. 6 depicts a schematic representation of a portion of a substrate comprising a plurality of features;

FIG. 7 depicts a schematic representation of images obtained across a portion of a substrate;

FIG. 8 depicts a flow diagram of steps in a method of determining a performance of lithographic patterning process;

FIG. 9 depicts a flow diagram with steps in a method of pre-processing an image for determining a performance of a lithographic patterning process;

FIG. 10(a) depicts a signal of a row of pixels away from a boundary between first and second regions;

FIG. 10(b) depicts a signal of a row of pixels near and/or on a boundary between first and section regions;

FIG. 11 depicts a flow diagram with steps in a method for determining metrics for determining a quality of a stitch.

FIG. 12 depicts a flow diagram with steps in a method of training a machine learning model for use in analyzing and determining a performance of a lithographic patterning process.

FIG. 13 depicts a two-dimensional matrix providing a schematic representation of the impact of overlay stitching error introduced in the x and y directions.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

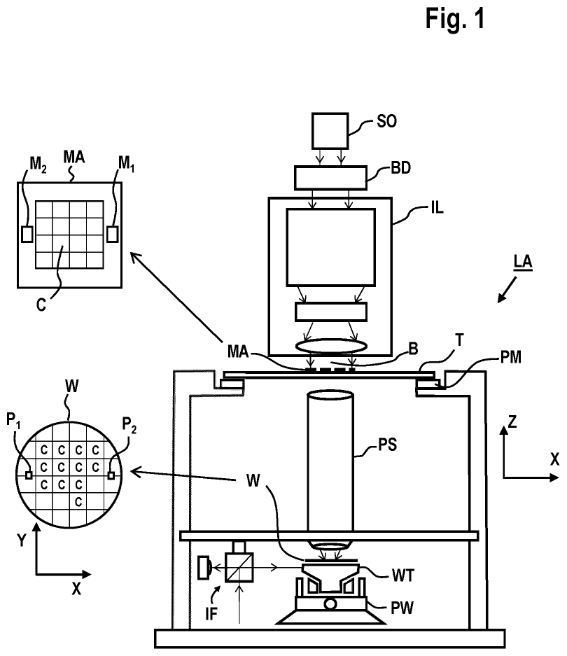

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support T, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

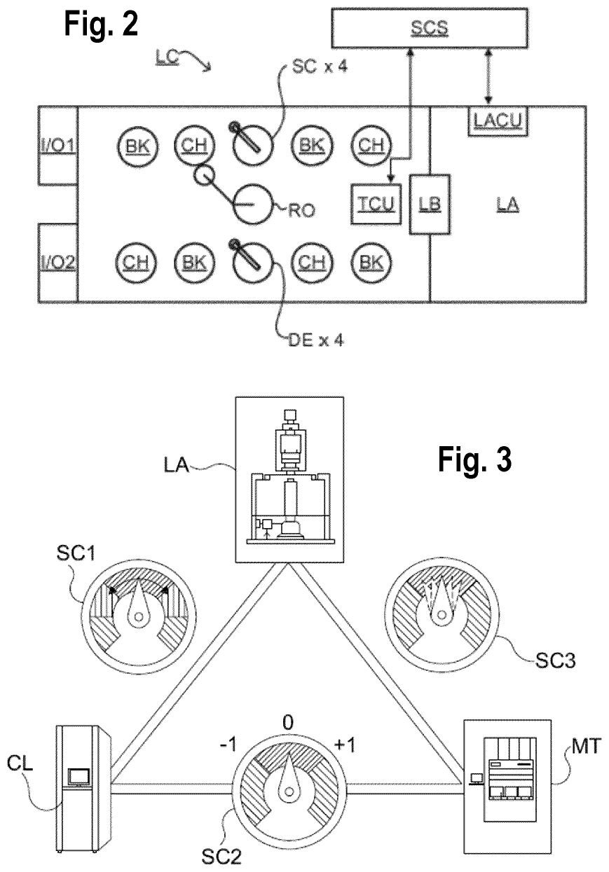

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequently measurements of the structures created, e.g., for process control and verification. Tools to make such measurement are typically called metrology tools MT. Different types of metrology tools MT for making such measurements are known, including scanning electron microscopes or various forms of scatterometer metrology tools MT. Scatterometers are versatile instruments which allow measurements of the parameters of a lithographic process by having a sensor in the pupil or a conjugate plane with the pupil of the objective of the scatterometer, measurements usually referred as pupil based measurements, or by having the sensor in the image plane or a plane conjugate with the image plane, in which case the measurements are usually referred as image or field based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers may measure gratings using light from soft x-ray and visible to near-IR wavelength range.

In a first embodiment, the scatterometer MT is an angular resolved scatterometer. In such a scatterometer reconstruction methods may be applied to the measured signal to reconstruct or calculate properties of the grating. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In a second embodiment, the scatterometer MT is a spectroscopic scatterometer MT. In such spectroscopic scatterometer MT, the radiation emitted by a radiation source is directed onto the target and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra.

In a third embodiment, the scatterometer MT is a ellipsometric scatterometer. The ellipsometric scatterometer allows for determining parameters of a lithographic process by measuring scattered radiation for each polarization states. Such metrology apparatus emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. Nos. 11/451,599, 11/708,678, 12/256,780, 12/486,449, 12/920,968, 12/922,587, 13/000,229, 13/033,135, 13/533,110 and 13/891,410 incorporated herein by reference in their entirety.

Examples of known scatterometers often rely on provision of dedicated metrology targets, such as underfilled targets (a target, in the form of a simple grating or overlapping gratings in different layers, that is large enough that a measurement beam generates a spot that is smaller than the grating) or overfilled targets (whereby the illumination spot partially or completely contains the target). Further, the use of metrology tools, for example an angular resolved scatterometter illuminating an underfilled target, such as a grating, allows the use of so-called reconstruction methods where the properties of the grating can be calculated by simulating interaction of scattered radiation with a mathematical model of the target structure and comparing the simulation results with those of a measurement. Parameters of the model are adjusted until the simulated interaction produces a diffraction pattern similar to that observed from the real target.

In one embodiment of the scatterometer MT, the scatterometer MT is adapted to measure the overlay of two misaligned gratings or periodic structures by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the wafer. The scatterometer may have a symmetrical detection configuration as described e.g. in co-owned patent application EP1,628,164A, such that any asymmetry is clearly distinguishable. This provides a straightforward way to measure misalignment in gratings. Further examples for measuring overlay error between the two layers containing periodic structures as target is measured through asymmetry of the periodic structures may be found in PCT patent application publication no. WO 2011/012624 or US patent application US 20160161863, incorporated herein by reference in its entirety.

Other parameters of interest may be focus and dose. Focus and dose may be determined simultaneously by scatterometry (or alternatively by scanning electron microscopy) as described in US patent application US2011-0249244, incorporated herein by reference in its entirety. A single structure may be used which has a unique combination of critical dimension and sidewall angle measurements for each point in a focus energy matrix (FEM—also referred to as Focus Exposure Matrix). If these unique combinations of critical dimension and sidewall angle are available, the focus and dose values may be uniquely determined from these measurements.

A metrology target may be an ensemble of composite gratings, formed by a lithographic process, mostly in resist, but also after etch process for example. Typically the pitch and line-width of the structures in the gratings strongly depend on the measurement optics (in particular the NA of the optics) to be able to capture diffraction orders coming from the metrology targets. As indicated earlier, the diffracted signal may be used to determine shifts between two layers (also referred to ‘overlay’) or may be used to reconstruct at least part of the original grating as produced by the lithographic process. This reconstruction may be used to provide guidance of the quality of the lithographic process and may be used to control at least part of the lithographic process. Targets may have smaller sub-segmentation, which are configured to mimic dimensions of the functional part of the design layout in a target. Due to this sub-segmentation, the targets will behave more similar to the functional part of the design layout such that the overall process parameter measurements resembles the functional part of the design layout better. The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717Alincorporated herein by reference in its entirety.

Different regions on a substrate may be exposed sequentially. For example, a reticle, or mask, may comprise a pattern to be exposed on a substrate a plurality of times. When exposing a layer on the substrate, the reticle may be moved relative to the substrate, in order to expose different regions on the substrate sequentially. As discussed above, a reticle may be associated with to a first positioner PM for accurately positioning the reticle inside a lithographic apparatus LA. A substrate W may be associated with a second positioner PW for accurately positioned the substrate W inside lithographic apparatus LA. The positioners PM and PW may be used to accurately position a substrate W and reticle relative to each other, in order to set a position of an exposed pattern on the substrate. Other settings and elements that may affect the position of a pattern on a substrate may include for example, the projection system PS for projecting the pattern of the reticle onto the substrate W, properties (e.g. topography) of the substrate, wafer table, WT, and properties of the radiation used for exposing a pattern.

In an example implementation, a full device to be lithographically exposed may be too big to fit on a single reticle. The full device may therefore be divided into two or more separate regions. The regions may be exposed separately from each other, for example sequentially. In order for the full device to work, the separately exposed regions need to be connected accurately and precisely at or proximal to a boundary between regions.

In order to position a plurality of sequentially patterned regions accurately, relative to each other, precise parameter control may be required. Settings of different elements of the lithographic apparatus LA may be optimised in order to obtain accurate positioning of exposed regions on the substrate. Measurement data may be obtained of an exposed substrate for determining the positioning of a plurality of regions. Measurement data may be used to check whether an exposed substrate has acceptable positioning of exposed regions, e.g. for quality control. Measurements may also be used to determine how to improve settings for future exposures performed by the lithographic apparatus LA. For example, positioning errors may be determined for a plurality of regions. The determined positioning errors may indicate that there is an error in the x-direction alignment of two neighbouring regions. The error may be analysed to determine one or more causes of the error. One or more apparatus or recipe settings may be updated to address the error, in order to avoid the mistake in future exposures.

Positioning of sequentially exposed regions relative to each other may be discussed in relation to stitching errors. The performance of a lithographic patterning process may comprise one or more stitching errors. Stitching errors may be errors in the desired position of exposed regions. Stitching may refer to the connection, or relative placement, of two regions. The regions may be neighbouring regions. The regions may comprise features having an association with each other. For example, the regions may belong to a same device exposed on the substrate W. The lithographic exposure may expose a pattern onto a two-dimensional region. The region may be rectangular. For example, a region may be square. However, the region may have any two-dimensional shape in the plane of the substrate. Along the borders of a region, a boundary with a neighbouring region may exist. In the case of a rectangular region, the directions along which the borders of a region lie may be referred to as the x-direction and y-direction. The directions of the borders may also be referred to as a horizontal and vertical directions.

As described above, the in-plane placement of exposed regions on a substrate may be controlled using measurement data. Measurement data may for example be used to determine and/or analyse stitching errors between regions on a substrate W. The measurement data may be obtained based on a metrology target. The metrology target may for example be an overlay metrology target. One or more metrology targets may be positioned on substrate as part of a pattern design exposed on the substrate. A metrology target may be exposed as part of the lithographic exposure. The structures included in the target (e.g. diffraction gratings) may be analysed to determine properties of the exposed pattern. Analysis of the metrology target(s) may comprise measurements to determine a position of one or more metrology targets relative to one or more further metrology targets on the substrate. The measurements may comprise for example overlay and/or alignment measurements. The metrology target(s) and further metrology target(s) may be positioned in different regions on the substrate. Including metrology targets adds costs by taking up space on the substrate W, as it leads to less space being available for exposing product features. On the other hand, including less metrology targets on a substrate may lead to sparse metrology data being available. This may in turn lead to decreased quality of analysis and/or control of the exposed patterns. Another potential drawback of using metrology targets for determining in-plane placement of regions, is that the measurement data may not be representative of the actual stitching error for the exposed features. The metrology target measurements may for example be designed and/or the pattern built up in a different way, meaning their behaviour is different. For example, the response of the pattern to aberrations and/or process effects of the exposure process may be different. The limited availability of metrology data, and the potential discrepancy between stitching error data and actual stitching errors, may present drawbacks for using metrology targets for in-plane positioning control. Described herein are methods and apparatuses to overcome at least some of these challenges.

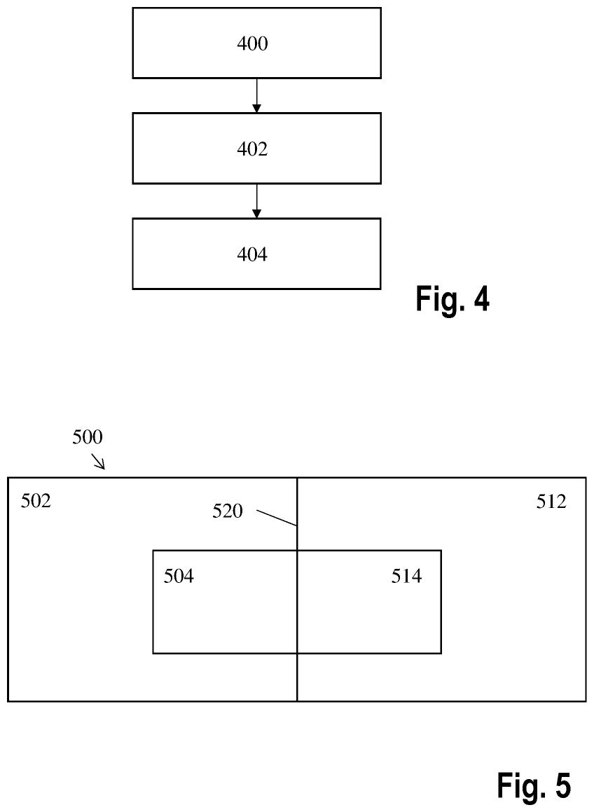

FIG. 4 depicts a flow diagram with steps in a method of determining a performance of a lithographic patterning process. The performance may be related to stitching of neighbouring exposed regions on a substrate. In step 400, at least one image of a portion of a substrate may be received. The portion of the substrate may comprise a first region comprising first features associated with a first lithographic exposure of the substrate at a first time. The portion of the substrate may further comprise a second region comprising second features associated with a second lithographic exposure of the substrate at a second time. The first and second regions may each comprise a portion that does not overlap with the other of the first and second regions. In a next step 402, one or more feature characteristics of the first and/or second exposed features may be obtained. The first and/or second exposed features may be associated with a boundary between the first and second regions. The first and/or second exposed features may for example be located at a boundary between the first region and the second region. In step 404 the performance of the lithographic patterning process may be determined based on the feature characteristics. The method described above, and other methods described herein, may be performed by an apparatus comprising one or more processors configured to perform the steps of the methods described herein.

FIG. 5 depicts a schematic representation of an image of a portion 500 of a substrate comprising first region 502 and second region 512. The first region 502 and the second region 512 may be separated along a boundary 520. The boundary 520 may comprise an outer border of first region 502 and an outer border of second region 512.

The first region 502 may comprise first features 504 associated with the first lithographic exposure. The second region 512 may comprise second features 514 associated with a second lithographic exposure. The first 502 and second 512 regions may be first and second exposure fields of a lithographic exposure process. The boundary 520 may comprise all or part of a border of the first field and all or part of a border of the second field. The first and second lithographic exposures may have been performed sequentially, at first and second times. Further exposures may have been performed between the first exposure and the second exposure. For example, one or more further regions may have been exposed lithographically, in between the first and second lithographic exposures of the first and second regions.

The first region 502 and the second region 512 may be neighbouring regions. The intended design of the first region 502 and the second region 512 may be nominally not overlapping. For example, a portion of outer border of the first region 502 may abut a portion of an outer border of the second region 512. However, in practice, the first region 502 and the second region 512 may partially overlap, for example because of errors in the patterning exposure, such as a stitching error. In other implementations, the first 502 and second 512 regions may have a partial overlap on the substrate. The first 502 and second 512 regions may have substantially the same size and/or shape. The shape of a region may be rectangular. The shape of a region may for example be square. A region may correspond to an exposure field on the substrate. One or more dimensions of a region may be in the range of 10 mm to 35 mm. For example, a region may correspond to an exposure field with dimensions of 26 mm by 33 mm, or 23 mm by 23 mm.

Determining the performance of a lithographic patterning process may comprise determining a quality of the patterning process. The quality may relate to how different regions that were exposed separately to each other are positioned relative to each other. Determining a performance may comprise determining a stitching error between a first exposure field 502 and a second exposure field 512. Determining a performance may comprise determining one or more properties of the exposed pattern, wherein the properties may be referred to as process features. Determining a performance may comprise determining one or more corrections for the patterning process. The corrections may be based on the determined process features and/or performance of the lithographic patterning process. The determined corrections may be used to update the lithographic patterning process for future iterations. Determining the performance of a lithographic patterning process may also comprise a verification of the patterning process.

The image may be a scanning electron microscope image (SEM). The image may be a voltage contrast image. A voltage contrast image may provide a measure of the electrical contact of features to the underlying layer. The image may be obtained after the exposed substrate has been processed, for example after one or more post-exposure development steps performed on the patterned substrate. The measure of contact to an underlying layer may provide an indication of how well the features of the exposed layer match up with features of an underlying layer. This may in turn be used to determine whether a stitching error is present. The image may be obtained while the substrate is in the lithographic cell LC. The image may be of a patterned layer of photoresist on the substrate. The image may be of a layer of material that has been patterned by an etching process.

The first features 504 and/or the second features 514 may be product features. That is to say, the method may use characteristics of features exposed on the substrate that are not related to a metrology target. The features 504, 514 may relate to a product structure to be exposed and patterned onto the substrate. For example, a substrate may be patterned with one or more devices. The first 504 and second 514 features may form part of the same device patterned on the substrate. The first features 504 and the second features 514 may be located in areas that have a common bounary. The common boundary may comprise some or all of boundary 520 between the first 502 and second 512 regions. An advantage of this method may be that the performance of the process is determined based on analysis of product features itself, as opposed to for example metrology target features. Another advantage may be that no or less metrology targets may be required, which may free up space on the substrate for product features. As more product features may be present on a substrate compared to metrology targets, using images of product features for analysis may allow taking dense measurements. This may result in a more detailed analysis of the performance, which may lead to increased accuracy. Because the analysis is not limited to areas of the substrate where metrology targets are present, the distribution and/or density of measurements may be tailored across the substrate. For example, areas of the exposed pattern where stitching is important for performance, or areas where past exposures have experienced stitching errors, may be measured more densely compared to other areas.

The first features 504 and/or the second features 514 may be dummy features. Dummy features may be exposed on a substrate to have similar properties and/or dimensions to product features. In this respect, one or more properties and/or dimensions of dummy features may be the same or substantially the same as corresponding properties and/or features of one or more product features. This may be so that analysis of the dummy features would provide similar results to analysis of product features. For example, the dummy features may have similar dimensions and/or shapes to product features. In some instances, the shapes of dummy features may be set so that feature characteristics may be obtained that may be suitable for analysis to determine the performance For example, the dummy features may comprise a variety of different features that may resemble product features from across the substrate, so that the variety of features may be found within a single image. Properties of dummy features may be designed to increase the sensitivity of the features to stitching errors. For example, the shape, dimensions, position, or dose of dummy features may be set so that they are sensitive to variations in stitching.

The first features 504 and the second features 514 may be first product features and second product features, respectively. In some instances, the first 504 and second 514 features may form part of different product features. In other instances, the first 504 and second 514 features may nominally comprise a single feature extending along the first region and the second region. Stated otherwise, the first features 504 and the second features 514 may comprise portions of the same product feature extending across the boundary between the first 502 and second 512 regions. An image may comprise a combination of first and second features comprising separate product features, and first and second features comprising a single product feature.

Determining the performance of a lithographic patterning process may comprise performing an analysis of the image to determine one or more feature characteristics. Analysis of the image may be used to determine feature characteristics of the first features 504 and/or the second features 514. The first and or second features may be associated with the boundary comprised in the image. In this context, associated with may mean the features are positioned at or near (proximal to) the boundary between the first and second regions. The feature characteristics may comprise a visual property of the first and/or second features in the image. The feature characteristics may comprise a spatial dimension of the first and/or second features. The feature characteristic may comprise a distance metric, which may be between the first features 504 and the second features 514. The distance metric may for example comprise a distance between one or more axes of symmetry of the first features 504 and one or more axes of symmetry of the second features 514. In case the first features and the second features do not constitute a single feature extending along the first 502 and second 512 regions, the distance metric may comprise a physical distance between the first features and the second features.

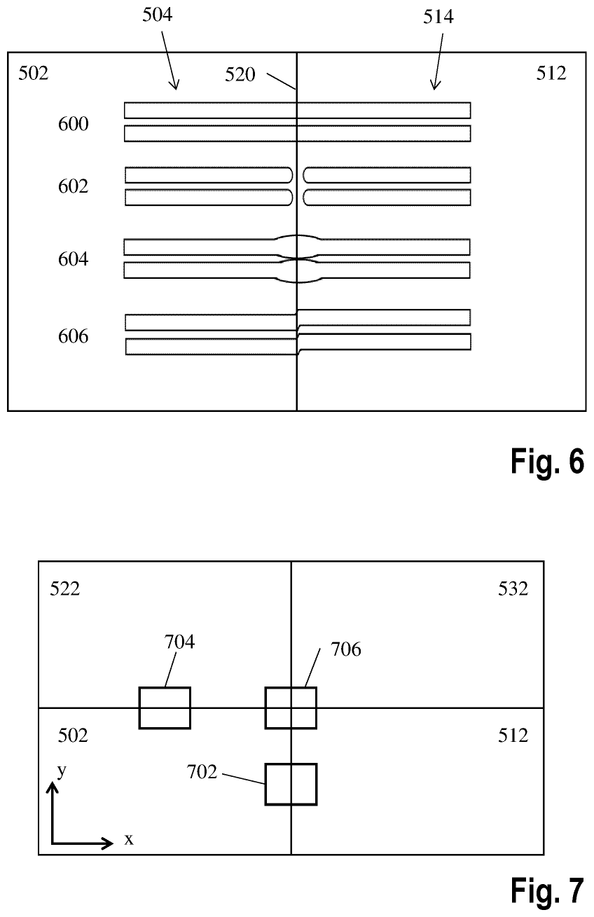

FIG. 6 depicts a schematic representation of several example feature characteristics. The feature characteristics in the first 502 and second 512 regions comprise a single example feature, consisting of two parallel lines crossing over boundary 520 between the first 502 and second 512 regions. The intended feature design to be exposed onto a substrate may be referred to as a design standard. Determining feature characteristics may involve comparing one or more spatial dimensions and/or other visual properties of a feature exposed on the substrate, to the design standard. Feature 600 may represent a feature according to the design standard of two parallel lines. Feature 600 does not comprise a stitching error. Single features crossing a boundary 520 may comprise a local thickening or narrowing at or proximal to the boundary between the first region 502 and the second region 512. In feature 602 the parallel lines are interrupted at boundary 520, so that they do not meet to form a solid line. Although feature 602 shows a full interruption of the parallel lines, in some instances the lines may instead experience a local narrowing around the boundary region 520. In feature 604, the parallel lines are wider (or thicker) around the boundary region 520. In feature 606 the lines in the second region 512 are displaced or offset in the direction parallel to the boundary 520, compared to the lines of the first region 502. If the stitching of the regions comprises an error, the performance of the resulting device may be reduced. For example, first features 504 and second features 514 may be designed to contact each other across boundary 520 for allowing current to flow between them. However, due to a stitching error, there may be a reduced contact or no contact between the first 504 and second 514 features. This may least to a reduced connection or no connection being made, inhibiting current flow. In some instances, a stitching error may cause the regions to have partial overlap, which may increase the size of the exposed features. This may cause features that are not supposed to contact to overlap, which may for example cause a short circuit.

Determining the performance of a lithographic patterning process may comprise determining the performance of one or more lithographic patterning process characteristics, also referred to as process characteristics. The determined feature characteristics may be used to determine one or more process characteristics. Example process characteristics include translation in the x and/or y directions, magnification, focus, dose, etc. in the first region 502 and/or the second region 512. Example process characteristics may also comprise one or more higher order deformation errors associated with patterning of the first regions 502 and/or the second region 512. In FIG. 6, the narrowing and/or interruption of the parallel line at boundary 520 may indicate that the magnification of the exposed features in the first 502 and/or second 512 regions is too small. The local thickening of the lines at boundary 520 in feature 604 may indicate that the magnification of the exposed pattern in the first 502 and/or second 512 regions is too large. Feature 604 may indicate a translation error of the first region 502 relative to the second region 512 along the dimension parallel to boundary 520.

A combination of analyses of multiple feature characteristics may be used to determine process features. This may for example comprise an analysis of features characteristics for differently shaped features in the first 502 and/or second 512 regions. Example features include straight lines, dots, larger area features, etc. The lines may be perpendicular to the boundary 520, or the lines may be positioned at a non-perpendicular angle to the boundary 520. A combination of differently shaped features may for example be obtained by exposing and imaging dummy features on a substrate.

Determining process characteristics may also be performed based on feature characteristics obtained from a plurality of images. For example, in order to determine the quality of stitching around a region, images of different parts along the boundary may be used. Different images may provide a boundary along different in-plane dimensions on the substrate. For example, a first image may be provided comprising a first boundary between a first region and a second region. A second image may be provided comprising a second boundary having a different direction to the first boundary. The second boundary may be between the first region and a further region. The further region may be the second region (same as for the first boundary), or a third region, associated with a third lithographic exposure on the substrate at a third time, separate from the first and second exposures.

A plurality of images may be received for determining a performance of a patterning process. A first image and a second image may comprise boundaries in first and second directions, wherein the first and second directions are not parallel. The first and second directions may be perpendicular. The first image and the second image may both comprise a boundary comprising a portion of an outer border of a first region 502. For example, in the case of a rectangular region, a first image may be received comprising a portion of a boundary in the x-direction, and a second image may be received comprising a portion of a boundary in the y-direction. The x- and y-directions may form the plane of the substrate.

FIG. 7 depicts a schematic representation of a portion of a substrate comprising regions 502, 512, 522, 532. Each of the regions 502, 512, 522, 532 may have been lithographically exposed at a different time. Each of the regions 502, 512, 522, 532 may be a separate exposure field. A first image 702 may be provided, comprising a boundary between region 502 and region 512. The boundary of image 702 may extend in the y-direction. A second image 704 may be provided, comprising a boundary between region 502 and region 522. The boundary of the second image may extend in the x-direction. One or more process characteristics may be determined for the first image 702 and the second image 704 separately. The process characteristics from the first 702 and second 704 image may then be combined to determine a performance of the patterning process. As well as using two images, process features determined from three or more images may be combined to determine a performance of the patterning process. Alternatively or additionally, an image 706 may be provided of a corner portion of region 502. This image may comprise a portion of boundaries in both x- and y-directions.

The method of analysing and determining a performance of a lithographic patterning process may be performed for multiple layers on the same substrate. The image may be taken of the substrate in between subsequent exposure steps. The performance may be analysed after every exposure that comprises stitching of regions on the substrate. An advantage of the methods described herein may be that they enable the substrate to be measured for example by obtaining an SEM image. This may increase the speed of the process of determining the performance of the lithographic patterning process compared to diffraction-based measurements, which are slow to obtain compared to SEM metrology.

The determined process features may be used to determine the performance of the lithographic patterning process. The performance may comprise for example an assessment of the quality of the process, a verification of the features exposed by the process, and/or a determined stitching error for the exposure. The method may also determine one or more corrections to the lithographic patterning process. The lithographic patterning process may be updated with the one or more corrections for future iterations. Updating the patterning process may comprise updating at least one or more exposure settings of the lithographic apparatus LA, and a reticle design.

The method may receive a plurality of images spread across different positions on the substrate for determining the performance of a lithographic patterning process. Determining the performance of the lithographic patterning process may comprise determining an overall quality of the exposure, and/or may comprise a localised assessment of the quality. Process characteristics may be determined for each of the images, and may be combined for determining an overall quality of the lithographic patterning process. In other implementations, one or more images located closely together on the substrate may be combined to determine a separate, localised, determination of the process performance at that position on the substrate. The feature characteristics and process characteristics may be determined at different positions on a substrate, as stitching errors may vary across a substrate. This may be used to determine stitching errors across different positions on the substrate. This may allow the performance of the lithographic patterning process to be determined across the substrate. If the performance is measured on product features, the method may provide flexibility in the amount of images analysed to determine the process performance The density of measurements may be set depending on the requirements of the performance analysis, e.g. the precision and accuracy required for the product features exposed on the substrate. The method may determine a dense map or a sparse map of performance across the substrate. A substrate may comprise in the order of 100 regions. The method may determine a performance for a number of regions between five regions and all regions on the substrate. The measurements may be spread evenly across the regions of the substrate. For example, if there are four measurement locations per region (e.g. 4 metrology targets), each of the measurement locations may be used for 25% of the regions. Per region, a plurality images may be obtained for determining stitching errors. The images may relate to the same boundary having the same first 502 and second 512 regions, or to different boundaries between a first region 502, and second 512, third 522, fourth 523, etc. regions. The method may use between 4 and 20 images per region. In some instances, the method may use more than 20 images.

The same lithographic patterning exposure may be performed on a plurality of substrates over a period of time. The amount and positions of images to be analysed for determining the performance of the patterning process may be changed over time. When a new exposure pattern starts, a more dense performance map may be prepared, as the new process may require more corrections initially. Once the process settings have been corrected one or more times, the performance may improve, and/or stabilise. In response to this, the amount of images analysed to determine process performance may be reduced. The method may also be flexible how dense the performance analysis is across the substrate. The method may determine one or more areas of interest for performance analysis. For example, areas where the determined performance is worse may be analysed in more detail when performing that same exposure on another substrate. As another example, a substrate may comprise critical areas, where product features may have more stringent fabrication requirements (i.e. lower tolerances on deviations from the design standard). These critical areas may receive more dense performance monitoring. This may lead to improved performance of the patterning process at the critical areas.

The methods of determining a performance of a lithographic patterning process may be determined in whole or in part using a model. The model may comprise vision technology, for example machine vision technology. The model may be a machine learning model. A model may be used to determine one or more process characteristics. In an example implementation, a model may receive one or more feature characteristics as input. In another example implementation, a model may take as input one or more received images of the first and second region and boundary 520. A method may use a plurality of models. A method may for example use two separate models. A first model may be a vision technology model. The vision technology model may be used for interpreting one or more images provided as input to the model. A model receiving one or more images as input may be a convolutional neural network. The first model may provide one or more process characteristics as output. A second model may receive one or more process characteristics determined by the first model. The second model may receive process characteristics for a plurality of regions on a substrate. The second model may interpret the received process characteristics to convert them to patterning corrections. The second model may provide as output, correction data for adjusting the lithographic patterning process, for example for correcting stitching errors. For example, the correction data may comprise one or more updated values for lithographic patterning process settings. A model may the model may comprise a classification model. The classification model may for example be for verification of the patterning process. For example, the model may classify an image as having region stitching properties falling within (pass) or outside (fail) of one or more set exposure tolerances.

The methods as described herein may use one or more images to determine feature characteristics of patterns depicted in those images. The feature characteristics (e.g. overlay, alignment, or other properties indicating a stitching quality) may be determined directly from analysis of the image. In order to detect small changes or variations in feature characteristics, it may advantageous to enhance the quality of the image(s) prior to analysis of the image(s) for determining the feature characteristics. Enhancing an image may for example comprise removing noise, filtering out unwanted signals, and/or extracting relevant features to the analysis. An advantage of extracting relevant features may include a reduction in dimension of the analysis. As described herein, determining one or more feature characteristics from an image may comprise some or all steps of pre-processing the image, extracting features from a pre-processed image, and/or determining a metric for a stitching quality based on the pre-processed image.

The feature characteristic may comprise overlay. It may be desirable to separate an analysis of overlay into separate dimensions on the substrate, for example the two dimensions in the plane of the patterned substrate. The dimensions may be perpendicular to each other, and may be referred to as a x-direction and y-direction, or a horizontal direction and a vertical direction. These directions may be parallel and/or perpendicular to the directions of the boundaries to be analysed.

The pre-processing of an image may comprise a step to remove noise from an image. The pre-processing may preserve the structural information related to the pattern present in the image. In particular, the pre-processing may be configured to preserve information relating to edges and/or strips present in the image. Edges, strips, or other borders on an image may also be referred to as line features. Pre-processing of the image may include determining intensity information and/or gradient information for the image. The intensity and/or gradient information may be used to determine a segmentation of the image. The segmentation may enable at least some of localisation of edges and/or strips, removing background and/or noise in the image.

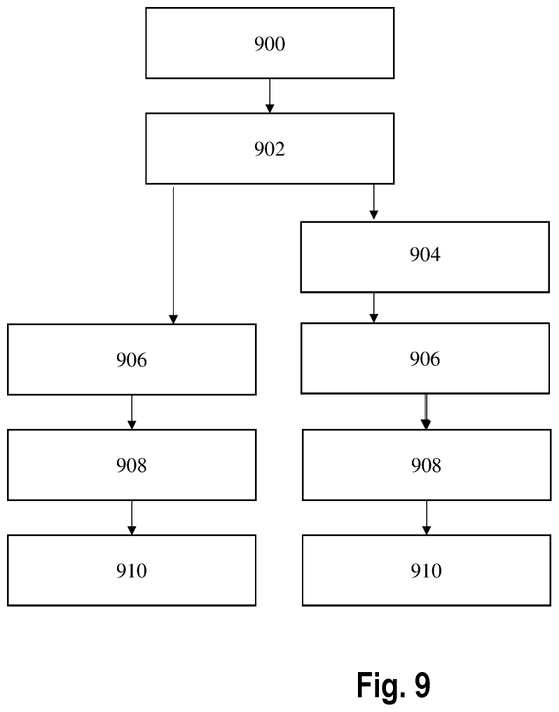

FIG. 9 depicts an example of steps in a method for pre-processing an image for determining a performance of a lithographic patterning process. In step 900 the image may be upsampled. The upsampling may comprise an interpolation, for example a bicubic interpolation. The skilled person will appreciate that any suitable upsampling method may be used. In step 902 the upsampled image may be processed to suppress and reduce noise present in the image. In step 904 a gradient magnitude, also referred to simply as a gradient, may be obtained of the image as processed up to that point. The gradient may provide an advantage of highlighting edges present in the image. In step 906, the image as processed in step 902 and or 904 may be processed to form a binary image. In this context, a binary image may be an image in which the data has been compressed to be expressed in a binary way, i.e. as one of two possible values. A binary image may be an image wherein each pixel has one or two possible values, e.g. 0 or 1, black or white, yes or no, etc. This may be represented as a black-and-white image, or an image with any other combination of two different colours. In step 908 the binary image may be processed to be cleaned up. Cleaning up the binary image may comprise filling in holes in the binary image and/or removing islands of pixels, for example by deleting the islands, or connecting them to other regions. Cleaning up the binary image may for example use region growing techniques and/or connected component techniques. In step 910 the pre-processing may perform a rotation of the processed image. The rotation may be determined so that edges and/or strips in the processed image are parallel and/or perpendicular to the boundary between the first and second regions in the image. In some instances multiple binary images may be formed. For example, a first binary image may be formed of the upsampled image, and a second binary image may be formed from the gradient magnitude of the image. Processing steps 908-910 may be performed on both binary images. The processed first and second binary images may be analysed in parallel. An advantage of this parallel analysis may be that it enables obtaining a more consistent and robust overlay determination compared to analysis of the image by itself. As shown in FIG. 9, the flow diagram splits into a first arm representing forming a binary image of the upsampled image, and a second arm representing forming a binary image of a gradient magnitude of the image. In the methods disclosed herein, at least one of the arms may be executed as part of the pre-processing of the image.

The noise-reduction technique of step 902 may be edge-preserving. The noise reduction technique may for example comprise one or more of bilateral filtering, anisotropic diffusion filtering, and/or an unsupervised wavelet transform. If the amount of noise in an image is not sufficiently reduced, the steps performed to detect and identify line features may comprise mistakes, for example due to noise being mistakenly identified as a line. In order to improve noise reduction, he an autoencoder model may be used. The autoencoder model may be a denoising autoencoder. The autoencoder model may comprise a machine learning model. In particular, the autoencoder model may comprise a convolutional neural network CNN and/or a generative adversarial network GAN. A GAN may comprise a generative network that produces a noiseless image, and a discriminator network classifies the output of the generative network. The autoencoder may be trained to generate a noiseless or reduced noise image without producing image artefacts. The autoencoder may be trained on pairs of noisy/noiseless images. The training pairs may be obtained using simulations, for example by adding different types of noise.

A binary image may be formed by segmenting the processed image and/or the gradient magnitude of the determined for the processed image in step 904. Methods that may be used to determine a binary image may include thresholding methods, such as global thresholding methods. A global thresholding method may for example comprise the Otsu image processing method. Method for determining a binary image may alternatively or additionally include machine learning methods. Example machine learning methods for creating binary images may for example comprise clustering. The clustering algorithms may use a mixture of Gaussian components. The machine learning algorithm may for example take the processed image and a gradient of the processed image as inputs.

In step 910, the pre-processed image may be analysed to determine whether edges/line features in the image have a rotation relative to the edges of the image. If the images comprises edges and/or strips at multiple different angles, a main direction may be determined, and the rotation may be performed to align the main direction. The main direction may for example be the direction of line features present most frequently in the image. If the direction of the line features of an image is not perpendicular/parallel to the boundary between the first and second region in the image, or if the image has an otherwise undesired rotation, the method may determine a rotation to be applied. The method may then apply the rotation to the image. To detect a direction of the edges, line detection techniques may be used for detecting lines and determining their angles. The line detection technique may for example comprise a Hough transform to detect line features and their angles in the image. The method may then use an image rotation algorithm to rotate the image by the amount determined by the line detection technique.

Pre-processing of an image may include some or all of the steps of FIG. 9. If a plurality of images are used to determine a performance of a lithographic patterning process, pre-processing may be performed on at least one of the plurality of images. Pre-processing may be performed in each of a plurality of images used for determining a performance of a lithographic patterning process.

The performance of a lithographic patterning process may be determined based on one or more feature characteristics. These feature characteristics may be identified from the image. The one or more features may be extracted from the image and/or from the pre-processes image. The features may be used to determine a stitching quality at the boundary between the first region and the second region shown in the image. The stitching quality may for example be assessed in terms overlay OVL between the first region and the second region at the boundary. The stitching quality may be determined in two directions in the plane of the substrate, for example the x and y directions mentioned above. The features patterned on the substrate may comprise line features parallel to one of the two directions, and perpendicular to the other one of the two directions. The features may alternatively or additionally comprise line features at an angle that is not parallel/perpendicular to the directions. The angle may be any angle from 0 degrees to 90 degrees.

One or more features may be extracted from a pre-processed image using a feature extraction algorithm. The feature algorithm may use a Fourier transform on the pre-processed binary image. If the binary image comprises line features that are parallel to the X direction, a Fourier transform may be applied to portions of the image parallel to the Y direction. Similarly, if the binary image comprises line features that are parallel to the Y direction, a Fourier transform may be applied to portions of the image parallel to the X direction. The portions may be row of pixels of the image. The Fourier transform may be a Fast Fourier Transform (FFT). A row of pixels along which a Fourier transform may be applied may be aligned to a direction of the boundary in the image. The pixel rows may be parallel to the boundary, or may be substantially parallel to the boundary. In some instances, for example if the boundary between the first and second regions is misplaced due to stitching errors, the boundary may be not quite parallel to the pixels rows. This misalignment may become apparent as part of the analysis of the differences between pixel rows.

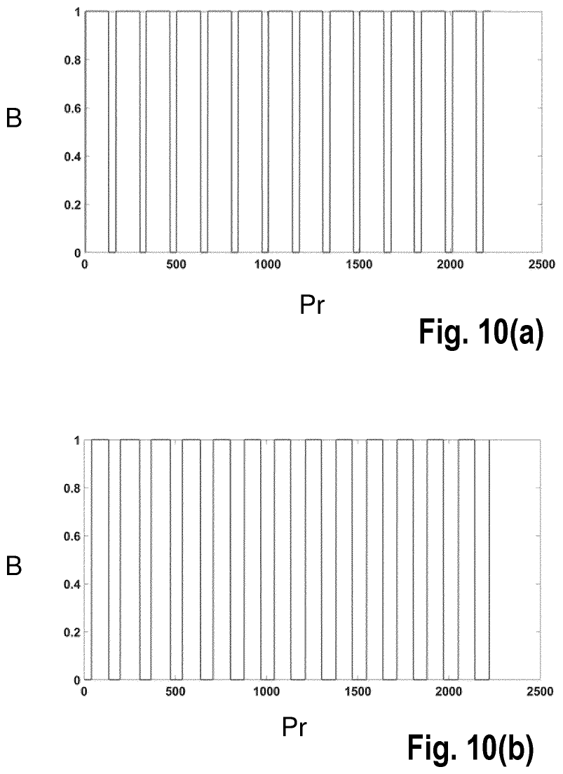

FIG. 10 shows a graph of a signal pattern on a row of pixels, wherein the Pr axis represents the pixels in the row. The axis labelled B indicates the binary value in the pre-processed binary image input for that row. The rows of pixels may be substantially perpendicular to the line features in the image. FIG. 10(a) represents a signal of a row of pixels away from the boundary between the first and second region. The row is sufficiently far away from the boundary between the first and second regions, so that no stitching effects are present in the row. FIG. 10(b) represents a signal on a row of pixel on or in the vicinity of the boundary between the first and second regions. As can be seen from the figures, the location of the edges/line features differs between FIGS. 10(a) and 10(b). This may indicate that stitching effects are present in the row of pixels at/near the boundary. Although the methods described herein refer to pixel rows, the same method can be applied to columns of pixels, wherein the boundary between the first region and the second region is not parallel (e.g. perpendicular) to the columns of the image.

A Fourier transform may be performed on each row of pixels. From the Fourier transform, one or more of the duty cycle, the frequency magnitude, and the phase component may be determined for each row. A duty cycle may be an indication of where in the binary image the line features are located. As the line features may represent edges of strips crossing a boundary, the position of the lines may be an indication of the width of the strips at that pixel row. This width may be expressed as a duty cycle. A change in duty cycle between different rows may indicate a difference in width of a line feature along a direction parallel to the line feature. A determined change in duty cycle around the location of the boundary between the first and second regions may be used to detect a stitch location. The duty cycle change may also be used to determine a quality of the stitching between the first and second regions. The period of the signal in the rows at and around the boundary may also be used to detect and assess the quality of a stitching location.

A change of phase between different rows may be used as an indicator of a stitching error in a direction perpendicular to the line features. A change in duty cycle may be used as an indicator of a stitching error in a direction parallel to the line features.

Alternatively or additionally to performing a Fourier transform of a binary image, a Fourier transform may be performed on a pre-processed image representing a gradient detected in the image. A combination of a binary image analysis and a gradient image analysis may improve the accuracy of the determination of the feature characteristics. Using both a binary image analysis and gradient image analysis may further enable error detection and/or consistency checks of the feature characteristic determination.

In a first example, an image comprises a plurality of vertical strips reaching across a horizontal boundary from a first region to a second region. Using a Fourier transform, a duty cycle and a phase can be determined for a plurality of horizontal rows of pixels of a pre-processed image. The determined phase difference between the rows may then be used to determine overlay or other stitching quality indicator in the horizontal direction. The change in duty cycle across the rows may be used to determine overlay or other stitching quality indictor in the vertical direction. In an example implementation, the maximum phase change between pixel rows of the first region (above the horizontal boundary), and pixel rows in the second region (below the horizontal boundary) may be used as an indicated of the stitching quality in the horizontal direction. The maximum duty cycle change between rows at an area near the boundary, and the duty cycle of rows in an area away from the boundary (in an area of the image not affected by stitching effects) may be used as an indication of the stitching quality in the vertical direction.

The differences in duty cycle and/or phase may be averaged over several values, which may improve the signal to noise ratio for the determined differences. The duty cycle and/or phase measurements may be used for further analysis of the image, for example for performing a qualification of the noise. For example, the position of the phase variation, and the stability of the phase between the different rows may be used as an indicator of a confidence level for the determined stitching quality. Large changes in phase for line features which are expected to be straight, particularly in areas away from the boundary, may indicate a low confidence level.

Stitching quality data may be collected at several discrete areas and/or a larger area along the same boundary, for example using multiple images. The stitching quality data may all relate to the same stitch performed between the first region and the second region. The determined stitching quality along different points of the stitch may be used to determine an average stitching quality for the stitch. Stitching quality data may also relate to a plurality of different stitches. The determined stitching quality across the different stitches may be analysed to identify trends. The analysis may include statistical analysis, for example determining a moving average trend. The stitching quality may be analysed to qualify local edge placement errors. The stitching quality may be analysed to qualify the overall stitching performance. Overall stitching performance may for example be used to determine a performance of and/or corrections to a lithographic patterning process over a larger area of a substrate.

Determined duty cycle differences and/or phase differences may not provide a direct measure of overlay in a vertical and/or horizontal direction. Further data processing steps may be required to determine overlay based on duty cycle and/or phase differences. If the line features are not connected at the boundary, there may be pixel rows of the binary image near the boundary that comprise no line feature values. Such a row may be referred to as a zero duty cycle row. The number of zero duty cycle rows may provide an indication of overlay in a direction perpendicular to the boundary. The location and/or shape with which the duty cycle and/or phase changes around the boundary region may be used to determine the nature of the stitching quality.

The determined duty cycle difference and phase difference may be signed values. Taking an example of parallel strips extending across a first region and a second region across a boundary, if the first and second regions are pressed closer together than they are designed to be, the duty cycle may increase around the boundary. If the first and second regions are positioned further apart than they are designed, the duty cycle may decrease around the boundary region. The sign of the determined duty cycle difference may indicate which of the situations is represented by the difference.

As described above, one or more images comprising a plurality of line features, for example a pre-processed binary image of a periodic set of strips, may be used to determine an overlay in the directions parallel to and perpendicular to a boundary forming a stitching area between a first region and a second region. Overlay may be determined based on differences in duty cycle and/or phase across rows of pixels. To determine overlay in a direction parallel to the boundary, the determined phase difference may be a direct indicator. A value of overlay may be determined based on the determined difference in phase.

For determining overlay in a direction perpendicular to the boundary, additional data processing may be required to determine an overlay on top of the determined duty cycle difference. Next to the duty cycle difference, the location and shape of duty cycle changes/differences may be used to determine overlay. Material properties may also affect how the duty cycle is affected by changes in overlay, so information relating to materials used on the patterned substrate may also be used to determine overlay. In order to determine overlay in a direction perpendicular to the boundary, a model may be used. Alternatively or additionally, a look-up table may be provided to determine overlay based on a duty cycle difference.

A look-up table may be provided that relates a duty cycle difference to an overlay value. Other information that may be provided to use a look-up table includes for example one or more of a location of a change in duty cycle across the pixel rows may also be provided, a shape of duty cycle change across pixel rows, the maximum phase difference, and/or the number of rows with zero duty cycle. The look-up table may be constructed in a set-up phase, using test measurements.

In some instances, the relationship between the one or more feature characteristics and the overlay may be non-linear. In order to qualify such a non-linear relationship, a fine resolution of overlay may be required. In order to provide a fine resolution of overlay, a model may be used. The model may be a machine learning model, for example a neural network. The neural network may be trained during a set-up phase to learn a relation between overlay in a direction perpendicular to the boundary, and differences and changes in duty cycle across rows of pixels parallel to the boundary. Alternatively or additionally to a neural network, nonlinear regression methods may be used. As the features relevant for determining overlay have already been determined, trough pre-processing and/or Fourier transforms to determine phase and duty cycle differences, it may not be necessary to provide a large-scale neural network trained on the images themselves. Instead, it may be possible to train a small scale neural network or other nonlinear regression method based on the relevant data. The relevant data may comprise one or more of duty cycle difference, shape, and location, phase difference, and number of zero duty cycle rows.

In an example implementation, an image is provided for determining a performance of a lithographic pattering process. The image is pre-processed, wherein pre-processing may comprise a noise reduction step using an autoencoder, and a segmentation step to determine a binary and/or gradient version of the image. The binary pre-processed images and/or the binary gradient of pre-processed images may comprise line features. The line features may be analysed to determine a stitch quality. The stitch quality may for example comprise overlay in the directions parallel to and perpendicular to the boundary. Fourier transforms may be performed on rows of pixels of the binary image to determine a duty cycle and a phase for the line features. Overlay in the direction parallel to the boundary may be determined directly from the Fourier transformed data. To determine overlay in a direction perpendicular to the boundary, a model or look-up table may be provided. The model and/or look-up table may be configured to receive input data relating to the Fourier transformed data, and output overlay in a direction perpendicular to the boundary. The analysis and processing of images as described above may be used for a pattern comprising a plurality of parallel straight structures, which may be perpendicular to a boundary between the first and second regions. However, the methods and systems described herein may be used for other patterns as well. The properties of the patterns may be taken into account when analysing and/or interpreting the Fourier transform of the (pre-processed) images. Information regarding the nature of the pattern to may for example be used to train a model and/or build a look-up table for linking duty cycle to overlay.

In an example implementation, connecting strips across the boundary between the first and second regions may have a difference critical dimension. Information about this difference in design may be provided to the system for determining a stitch quality. For example, a vector may be provided comprising expected duty cycle values for each row of pixels. The difference between expected duty cycle and observed duty cycle may be taken into account when determining a stitching quality. The vector may for example be provided to a model or regression method.

As described above, a stitching quality may be determined at a boundary between first and second regions. This may be in the form of overlay in x and y directions. Additionally or alternatively, metrics other than overlay may be defined to assess a stitching quality. Such metrics may for example consider the smoothness, flatness, and/or symmetry of a stitch. The metric may be determined based on one or more of the image, on a pre-processed image, or on other data associated with the image. A metric may be determined based on a plurality of any of the above.

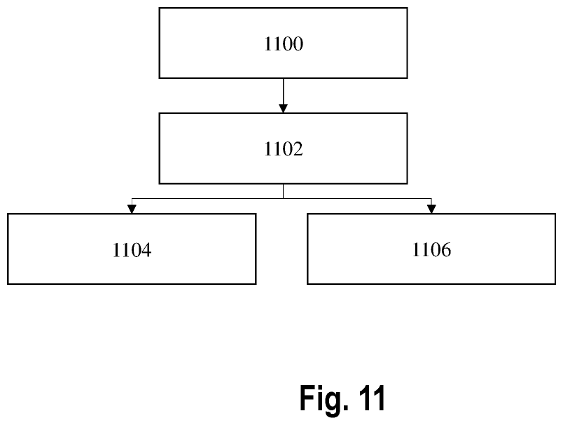

In an example implementation, a metric may be determined based on a binary image. The binary image may be a segmented binary image wherein the binary contrast is use to indicate edges and boundaries within the image. The binary image may have been filtered to reduce noise from the image. Methods may be provided to analyse a binary image to determine a metric for assessing a stitching quality in the image. FIG. 11 depicts a flow diagram with steps in a method for determining metrics indicative of a quality of a stitch. In step 1100 a binary image comprising a stitch between a first region and a second region is analysed to find turning points before and after the stitch. A turning point may be considered to occur at the start of a large change in duty cycle around the stitch. A turning point may be determined on both sides of the stitch area, that is to say, a turning point may be determined in both the first region and the second region. In step 1102 the area between the turning points may be copied at stored separately. The binary pixels indicating the edge may be stored as a curve. The horizontal axis of the curve may be the pixel row along the strip reaching across the boundary. The vertical axis of the curve may represent the duty cycle of the corresponding pixel row. A function may be determined that represents a mathematical expression of the curve.

The curve determined in step 1102 may be seen as representing the stitch between the first and second regions. In step 1104 the curve may be used to calculate a metric that demonstrates a flatness of the stitch. In order to calculate the metric, the curve may be considered as a probability distribution function. The flatness metric M_{flat} at may be calculated as a fourth order statistical moment of the function representing the curve. The formula for the flatness metric M_{flat} may be calculated as follows:

$${M}_{flat} = \frac{M {\sum }_{i = - n}^{n} f ( {x}_{i} ) * {( {x}_{i} - \overline{x} )}^{4}}{{( {\sum }_{i = - n}^{n} f ( {x}_{i} ) * {( {x}_{i} - \overline{x} )}^{2} )}^{2}}$$

In the above formula, f (xᵢ) may represent the value of the curve (the duty cycle) at the pixel location xᵢ. The pixel rows of the curve may reach from −n to n on the horizontal axis. M and x may be determined as follows:

$$\overline{x} = \frac{{\sum }_{i = - n}^{n} ( f ( {x}_{i} ) {x}_{i} )}{{\sum }_{i = - n}^{n} f ( {x}_{i} )} M = {\sum }_{i = - n}^{n} f ( {x}_{i} )$$

For the flatness metric above, a value of 0 represents a flat stitch. The flatness metric M_{flat} may be used to assess the quality of the stitch between the first and second region. The metric may for example be provided as an input to a model as discussed above to determine an overlay for the stich area.

In step 1106, the curve determined in step 1102 may be used to calculate a metric that demonstrates the skewness/symmetry of the curve around a central location of the stitch. The central location of the stitch may be the position where the stitch is designed to be positioned, that is to say, the designed boundary between the first region and the second region. As mentioned above, the curve may be considered as a probability distribution function. The skewness metric M_{skew} may be calculated as a third order statistical moment of the function representing the curve. The formula for the skewness metric M_{skew} may be calculated as follows:

$${M}_{s k e w} = \frac{\sqrt{M} {\sum }_{i = - n}^{n} f ( {x}_{i} ) * {( {x}_{i} - \overline{x} )}^{3}}{{( \sqrt{{\sum }_{i = - n}^{n} f ( {x}_{i} ) * {( {x}_{i} - \overline{x} )}^{2}} )}^{3}}$$

Wherein M and x̅ are defined as set out above. The above M_{skew} value is signed, wherein the sign may indicate whether the curve is skewed towards the first or second region. For the skewness metric formula defined above, a symmetric stitch with no skew would have a skewness metric value M_{skew}=0.

In some instances, the one or more images may be obtained by an entity controlled separately from the method described herein. In other instances, the method may include controlling a metrology tool MT to obtain one or more images of the substrate. The one or more images of the exposed regions on the substrate may be for example a scanning electron microscope (SEM) images, or voltage contrast images. The metrology tool MT may be an electron beam imager. The results of a previous performance determination may be used to guide a metrology apparatus to obtain images on the substrate. As described above in more detail, the results of previous performance determination may be used to determine which images to obtain, for example based on determined areas of interest. This previous performance information may guide where on the substrate to obtain images, and/or the density of the images across the substrate.

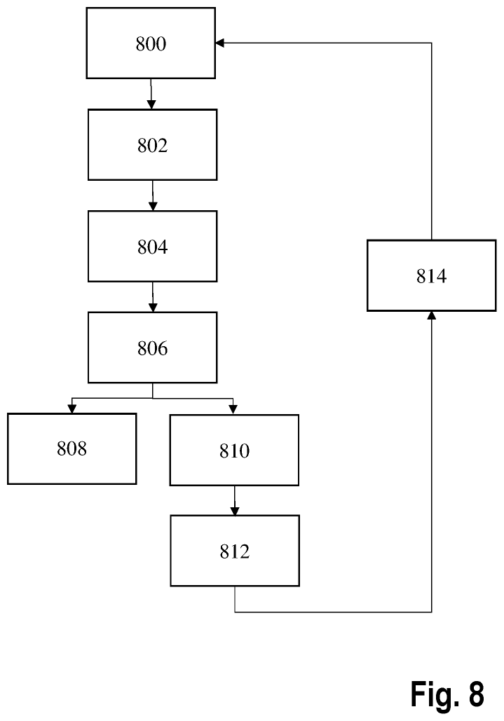

FIG. 8 depicts a flow diagram of steps in an example method for determining the performance of a lithographic patterning process. In step 800 one or more images are received of portions of a substrate comprising first 502 and second 512 regions, as described above. In step 802, the one or more images may be analysed to determine one or more feature characteristics of product and/or dummy features exposed on the portion of the substrate shown on the image. In step 804, the feature characteristics may be analysed to determine one or more process characteristics of the lithographic patterning process. In step 806 the performance of the lithographic pattering process may be determined based on the determined process characteristics. Determining the performance may comprise a verification of the patterning process 808. The determined performance may also comprise determining (810) one or more process corrections, and updating 812 the lithographic patterning process for future iterations. The method may also comprise controlling and/or guiding 814 a metrology tool MT for obtaining images for a determination of the performance of a future iteration of the lithographic patterning process.

The methods as described herein, in particular the method of analysing and determining a performance of a lithographic patterning process, may be alternatively or additionally implemented by machine learning models. A machine learning model may be trained on a training set of images of a portion of a substrate. The portion of the substrate may comprise a first region comprising first features associated with a first lithographic exposure of the substrate at a first time, and a second region comprising second features associated with a second lithographic exposure of the substrate at a second time. The first and/or second features may have one or more known feature characteristics associated with a boundary between the first region and the second region. The known feature characteristics may be linked to a known performance of the lithographic patterning process. In this way, the machine learning model may be trained to learn how to analyse and determine the performance of the lithographic patterning process based on the images containing known feature characteristics linked to a known performance of the lithographic patterning process.

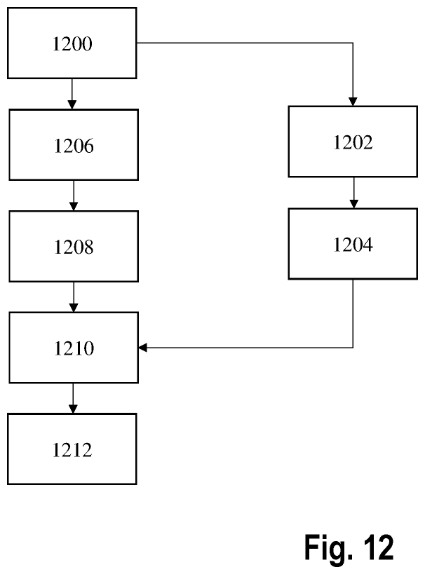

FIG. 12 depicts a flow diagram with steps in a method of training a machine learning model for use in analysing and determining a performance of a lithographic patterning process. The performance of the lithographic patterning process may comprise one or more stitching errors, as described herein. The machine learning model may be trained on a training set of images of a portion of a substrate comprising first features and second features having known feature characteristics linked to known stitching errors. Stitching errors may be associated with a particular feature characteristic, for example, overlay. In step 1200, a first lithographic exposure and a second lithographic exposure may be performed on a layer on a substrate. In this step, a plurality of known feature characteristics linked to a known performance may be deliberately introduced. For example, a plurality of known errors may be deliberately introduced. The known errors may be known stitching errors. The training set of images is thereby prepared. In step 1202, a measurement of the stitching error may be taken. The measurement may be an overlay measurement on an overlay target, or may be any known measurement used to determine stitching errors on a substrate. This step allows additional stitching errors (i.e. not the known stitching errors) to be identified. Such additional stitching errors may be introduced during the lithographic exposure process as described herein. In step 1204, measurements of the additional stitching errors may be used to update the training set of known stitching errors. In step 1206, the substrate may undergo the lithographic patterning process for which the performance is to be determined. In step 1208, at least one image of a portion of the substrate may be received. The at least one image may be an image as schematically represented in FIG. 5. In step 1210, the machine learning model may undergo a training process. The training set of known stitching errors along with the images received in step 1208 may be used to train the machine learning model to learn to identify stitching errors from the received images. Step 1210 may additionally comprise a validation process in which a validation set of known stitching errors and received images are used to validate the machine learning model. In step 1212, a metrology recipe used to obtain overlay values from the image data is determined.

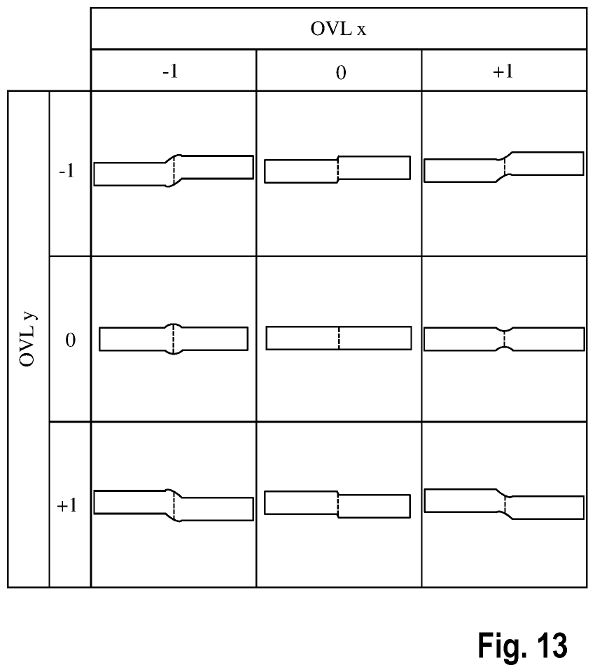

In step 1200, each of the plurality of known stitching errors may be introduced by, for example, imposing a translation of the second lithographic exposure relative to the first lithographic exposure, or vice versa. The plurality of known stitching errors may be introduced in more than one dimension. For example, the plurality of known stitching errors may comprise stitching errors introduced in the x and/or y directions. FIG. 13 shows a two-dimensional stitching error matrix providing a schematic impression of the impact of overlay OVL stitching error introduced in the x and y directions. Each entry in the matrix shows an identical line feature in the x direction. Matrix entry with x overlay 0 and y overlay 0 shows the feature when no stitching error is introduced (equivalent to the feature 600 in FIG. 6). Moving across the columns left or right of the 0,0 entry introduces overlay stitching error in the negative or positive x direction respectively. Moving across the rows up or down of the 0,0 entry introduces overlay stitching error in the negative or positive y direction respectively. It is noted that the positioning and structure of the line feature is a combined function of both x and y overlay. In other words, the x and y overlay are coupled. This is in contrast to diffraction-based optical measurements of overlay (or other feature characteristics) in which the x and y overlay are typically decoupled. This coupling of overlay can cause difficulty in separating out (or decoupling) the errors associated with x and y overlay when using image analysis techniques. By training a machine learning model on images with stitching errors introduced in both the x and y directions, the model will learn to identify both, regardless of the coupling. Advantageously, multiple lithographic exposures may be performed for each value of stitching error. This increases the size of the training set and thereby improves efficacy of the machine learning model. In addition, by performing multiple exposures for each value, the stitching errors unintentionally introduced during exposure may be ‘averaged out’. In other words, the impact of the stitching errors introduced during the lithographic exposure process is reduced.

As described previously process characteristics may be determined based on measurement of the stitching errors using any suitable method disclosed in this document, for example based on image analysis of a boundary area between two adjacent regions such as depicted in FIG. 7. The regions 502-512-522-532 may relate to individual (exposure) fields (full image of a patterning device at substrate level) or individual sub-fields relating to a portion of a field, for example a die area, cell area or an area associated with a particular control grid layout. Further background information on sub-fields and sub-field based control of a lithographic apparatus is disclosed in international patent application WO2016146217A1, which is herein incorporated by reference in its entirety.

In particular the translation errors between features lying in adjacent fields or sub-fields (in both X and Y directions) are of interest to determine said process characteristic. The process characteristic may then comprise one or more lower and higher order deformation errors associated with patterning of the first regions 502 and/or the second region 512. The deformation errors may be characterized by modelling the stitching errors (translation part) to a distortion model. The distortion model may be configured to describe an intra-field fingerprint representing said deformation error.

The deformation error is typically expressed as a distortion characterized by a set of distortion model parameters. The distortion model may be based on 2D polynomial base functions defined across a region (field or sub-field) on the substrate. The distortion may in particular be expressed as a linear combination of polynomials X\hat{ }m*Y\hat{ }n, for example according to the well-known k-parameter based configuration, wherein each k-parameter is associated with a certain physically relevant type of distortion. More information on k-parameter based modeling is disclosed in paragraph [0084]-[0085] of international patent application WO2017067752A1, which is hereby incorporated by reference in its entirety.

The chosen set of polynomial base functions may be orthogonal when defined across the field or sub-field area, for example the polynomial base functions may be a set of Legendre polynomials or Chebyshev polynomials, the latter disclosed in international patent application WO2011101192A1, which is herein incorporated by reference in its entirety.

Alternatively the distortion model may be based on spline (base) functions, for example Non-Uniform Rational Basis Splines (NURBS), as disclosed in international patent application WO 2019219285A1, which is hereby incorporated by reference in its entirety.

The distortion model parameter values are typically obtained by fitting a plurality of measured stitching errors to the distortion model base functions, each stitching error for example being associated with a particular (position) shift between a first part of a feature in said first region 502 and a second part of the feature in said second region 512 (boundary area along y-direction within image 702). The stitching errors may additionally comprise a plurality of measured stitching errors between a first part of another feature in said first region 502 and a second part of the another feature in a third region 522 (boundary area along x-direction within image 704).

The measured stitching errors may further be selected based on the criticality of the associated features. For example stitching error measurements related to features which are relatively tolerant to stitching errors (for example in case they have large dimensions or are less critical for the electrical properties of the semiconductor device comprising the features) may be omitted or receive a reduced weight factor when performing the fitting to the distortion model. Alternatively stitching errors may be averaged across one or more (different) types of features. In an example the stitching errors of a) isolated and b) densely distributed features are averaged to obtain stitching errors which are more representative for the range of product features provided to the first and/or second region on the substrate.

Alternatively the stitching error measurement data may be sorted per feature type or class to obtain multiple sets of stitching error measurement data. Each set of stitching error measurement data may be fitted separately to the distortion model to obtain multiple sets of distortion model parameters.

The obtained (sets of) distortion model parameters may subsequently be used to configure a lithographic apparatus used in patterning the regions on the substrate. In case multiple sets of distortion model parameters are available the configuring may be based on a weighted combination of individual sets of distortion model parameter (values). The weighting is typically based on the stitching error criticality of the feature(s) associated with the individual set of distortion model parameters.

In many cases intra-field distortion related information (known intra-field distortion component) is already available due to the availability of previously performed alignment, projection lens aberration and/or overlay measurements. This implicates that at least some level of knowledge on expected stitching errors is often available and may be used for one or more of:
a) verify the consistency of the measured stitching errors;
b) augmentation of the set of stitching error measurements, used in, for example, more accurately determining of the set(s) of distortion model parameters, improving the configuring of the lithographic apparatus;
c) de-correction of the stitching error measurements to isolate stitching errors (distortion) components associated with particular contributors. For example by subtracting the projection lens aberration induced stitching error component the contribution of wafer stage control to the stitching errors (and hence the derived distortion model parameters) may be quantified.

Intra-field distortion components known to have no or limited impact on feature placement at the boundary areas between the regions 502-512-522-532 may be excluded from being taken into account. For example an aberration induced distortion component which is symmetric around the centres of the regions 502 and 512 may be excluded from any of the uses a), b) or c) when applied to stitching error measurements associated with image 702.

In addition to known intra-field distortion components also field to field variation of the distortion components may be available (inter-field component) and/or field specific intra-field distortion components may be available (for example used in defining field specific control of the lithographic apparatus). Field to field variation may occur for example due to processing impact (for example due to CMP polishing steps and layer deposition steps inducing stress components). Field to field variation may also occur due to variation of field positioning (Translation Tx and Ty) and orientation (rotation Rz) caused by stage positioning limitations (thermal drifts, finite repro, sensor noise, etc.). In analogy to the use of known intra-field distortion components also knowledge on inter-field distortion components may be used to verify, augment or de-correct the measured stitching errors (or its derived distortion model).

The distortion model parameters derived from the stitching error measurements (either raw measurements or adjusted using knowledge of intra-field and/or inter-field distortion components) may be used to configure control parameters of the lithographic apparatus. These control parameters may be related to actuation of the projection lens, the wafer stage and/or the reticle stage during operation of the lithographic apparatus.

The (modeled) stitching errors occurring at the boundary areas may have one or more systematic intra-field components, for example based on generic properties of the projection lens aberration distribution across the regions 502-512-522-532 (intra-field distortion components) and/or generic properties of one more processes used in the patterning of the substrates (e.g. intra-field stress profile). At least part of the systematic intra-field component may be pre-corrected during the manufacturing of the patterning device (reticle) used in providing the features to the regions 502-512-522-532. For example the anticipated stitching errors may point towards a parabolically shaped position shift profile along the upper boundary of a region (lower part of image 704), while no particular position shift profile is expected at the lower boundary (upper part of image 704). The patterning device may now be manufactured/designed such that the parabolically shaped position shift profile is pre-corrected by adjusting the positions of the (product) features on the patterning device such that the expected position shift profile of the patterned (product) features is flat.

In many cases it may be preferred to modify an existing reticle using a method of local adaptation of the density of the reticle substrate material, in particular near features within one or more boundary areas for which stitching error data is available (either by direct measurement or based on already available knowledge). The adaptation of the density may be achieved by local exposure of the reticle substrate to a femtosecond laser pulse, as disclosed in international patent application WO 2017067757A1, which is hereby incorporated by reference in its entirety. Based on the stitching error data local reticle substrate density adaptation may be utilized to correct the position shift profile to a level that is either acceptable or correctable by control systems (actuators) of the lithographic apparatus.

Returning to the higher order distortion model, it has been disclosed that 2D polynomials are commonly used to describe the intra-field distortion. In particular k-parameters associated with polynomials representing physically relevant distortion components (barrel, cushion, etc.) may be used.

In some cases stitching error data for both a horizontally oriented boundary area (for example between region 502 and 522) and a vertically oriented boundary area (for example between region 502 and 512) is available. This is particularly relevant in case regions are stitched in two directions, X and Y. Fitting the stitching error data to the distortion model base functions (2D polynomials) needs to be done preferably in such a way that no crosstalk between model parameters occurs. This can be achieved by fitting model parameters associated with higher order terms of the coordinate which is constant across the boundary area (so Y for horizontally oriented boundary and X for vertically oriented boundary) in separate steps. In addition it is proposed to model the linear terms of the distortion model first, based on fitting the stitching error data for both boundary orientations (horizontal and vertical) in one single step to the linear (polynomial) base functions.

In summary the follow procedure is proposed: (1) Fit linear part of distortion model (e.g. x and y) to combined stitching error data along both the horizontal and vertical direction; (2) Remove linear content from stitching error data to obtain higher order stitching error data; (3) Model higher order stitching error data associated with horizontally oriented boundary area to higher order polynomial base functions X\hat{ }m*Y\hat{ }n, excluding m=0 to prevent risk of introducing crosstalk between the distortion model parameters; (4) Model higher order stitching error data associated with vertically oriented boundary area to higher order polynomial base functions X\hat{ }m*Y\hat{ }n, excluding n=0 to prevent risk of introducing crosstalk between the distortion model parameters; (5) Combine calculated distortion model parameters from step 1, 3 and 4, for a k-parameter definition the following model parameters are determined:
K3, K4, K5, K6 from step 1;
K9 and K10 by averaging results step 3 and 4;
K15 and K18 from step 3;
K16 and K17 from step 4.

The order of step 3 and 4 may be reversed, the proposed order is merely an example. The method is not limited to determining K-parameters up to K18, in case the stitching error data is densely distributed also higher order terms (K18+) may be determined, for example up to 5th, 7th or 9th order.

Further the procedure is not limited to determining K-parameters, also coefficients associated with orthogonal polynomial base functions (such as Legendre polynomials) may be determined according to the method described above.

In an embodiment a method is provided for characterizing a patterning process, the method comprising: obtaining a plurality of values of stitching errors made along one or more boundaries between at least two patterned adjacent fields or sub-fields on a substrate; and fitting a distortion model to the plurality of values to obtain a fingerprint representing deformation of a field or sub-field out of said at least two patterned adjacent fields or sub-fields.

In an embodiment the stitching errors are translation errors between first parts of features comprised within a first field or sub-field out of said at least two patterned adjacent fields or sub-fields and second parts of the features comprised within a second field or sub-field out of said at least two adjacent patterned fields or sub-fields.

In an embodiment the distortion model comprised distortion model parameters associated with 2D polynomial base functions.

In an embodiment the distortion model comprised distortion model parameters associated with spline functions.

In an embodiment the plurality of values of stitching errors include first values of stitching errors made along a first boundary between a first and a second adjacent field or sub-field and second values of stitching errors made along a second boundary between the first field or sub-field and a third adjacent field or sub-field, wherein the orientation of the first and second boundary is different.

In an embodiment the plurality of values of the stitching errors are associated with at least two different types of features and the distortion model is fitted to a subset of the plurality of values associated with one or more stitching error critical types of features.

In an embodiment the method further comprises assigning a weight factor to distortion model parameters associated with the distortion model based on a measure of criticality of the stitching error critical types of feature.

In an embodiment the obtaining of the plurality of values comprises weighted averaging of stitching errors associated with different types of features.

In an embodiment the weighting is based on on a measure of criticality of the type of feature.

In an embodiment the weighting is the same for each type of feature.

In an embodiment the method further comprises configuring a lithographic apparatus using parameters values associated with the fitted distortion model.

In an embodiment the method further comprises obtaining intra-field and/or inter-field deformation data; and perform one or more of: verifying consistency of the plurality of values of the stitching errors with the intra-field and/or inter-field data; combining the fingerprint with the intra-field and/or inter-field data to obtain an augmented fingerprint; de-correct the fingerprint to isolate one or more contributors to the fingerprint.

In an embodiment the method further comprises: manufacturing, designing or modifying a patterning device used in the patterning process based on the fingerprint or a systematic component isolated from the fingerprint.

In an embodiment the modification of the patterning device is based on local exposure of a substrate of the patterning device to laser pulses, wherein the length of the laser pulses are in the femtosecond range and cause local modification of the density of the material of the substrate of the patterning device.

In an embodiment the fitting of the distortion model is performed at least partially in separate steps, comprising at least a first step of fitting exclusively the distortion model to the first values of stitching errors and a second step of fitting the distortion model exclusively to the second values of stitching errors.

Further embodiments are disclosed in the list of numbered clauses below:
1. An apparatus for determining a performance of a lithographic patterning process, the apparatus comprising one or more processors configured to:

receive an image of a portion of a substrate, the portion of the substrate comprising a first region comprising a first feature associated with a first lithographic exposure of the substrate at a first time, and a second region comprising a second feature associated with a second lithographic exposure of the substrate at a second time, wherein the first and second regions do not overlap and wherein the first feature and the second feature form a single feature extending along at least part of the first region and at least part of the second region; and

determine the performance of the lithographic patterning process based on one or more feature characteristics of the first and/or second exposed feature associated with a boundary between the first region and the second region.
2. An apparatus according to clause 1, wherein the boundary comprises a portion of an outer border of the first region and a portion of an outer border of the second region.
3. An apparatus according to any of the preceding clauses, wherein the first feature and the second feature comprise at least one of product features, and dummy features having one or more dimensions the same as the product features.
4. An apparatus according to any of the preceding clauses, wherein the one or more feature characteristics comprise a distance metric comprising:

a distance between one or more axes of symmetry of the first features and one or more axes of symmetry of the second features; and/or

a physical distance between the first features and the second features.
5. An apparatus according to clause 1, wherein the substrate is a wafer.
6. An apparatus according to clause 1, wherein the one or more feature characteristics comprise a narrowing or a thickening of the single feature at or proximal to the boundary.
7. An apparatus according to any of the preceding clauses, wherein the first features and the second features form part of a patterned layer of photoresist or a layer of material after being patterned by an etching process.
8. An apparatus according to any of the preceding clauses, wherein determining the performance comprises analysing the image to determine one or more feature characteristics of the first and/or second features associated with the boundary between the first region and the second region.
9. An apparatus according to clause 8, wherein determining the performance comprises performing a comparison of the first and/or second features of the image to a standard for the first and/or second features.
10. An apparatus according to clause 8 or 9, wherein determining the performance further comprises determining a performance of one or more lithographic patterning process characteristics, based on the determined one or more feature characteristics.
11. An apparatus according to clause 10, wherein the one or more feature characteristics comprise a spatial dimension of the first and/or second features.
12. An apparatus according to clause 10 or 11, wherein the one or more process characteristics comprise one or more of magnification, translation, and/or a higher order deformation error associated with the patterning of the first region and/or the second region.
13. An apparatus according to any of clauses 10 to 12, wherein the performance of the one or more process characteristics is determined at least in part using a model taking as input at least one of the one or more feature characteristics.
14. An apparatus according to clause 13, wherein the model comprises a machine learning model.
15. An apparatus according to clause 14, wherein the model comprises a neural network.
16. An apparatus according to clause 15, wherein the model comprises vision technology.
17. An apparatus according to any of clauses 14-16, wherein the model is configured to be trained on a training set of images of a portion of the substrate comprising first and second features, wherein the first and/or second features of the training set images have one or more known feature characteristics linked to a known performance of the lithographic patterning process.
18. An apparatus according to clause 17, wherein each training set image comprises a portion of a training substrate comprising first features associated with a first lithographic exposure of the training substrate at a first time, and second features associated with a second lithographic exposure of the training substrate at a second time.
19. An apparatus according to any of clauses 17-18, wherein the known feature characteristics and performance of the lithographic patterning process are at least partially based on one or more measurements of one or more feature characteristics of the first and/or second features.
20. An apparatus according to any of clauses 17-19, wherein the known performance of the lithographic patterning process comprises a known stitching error.
21. An apparatus according to any of the preceding clauses, wherein determining the performance of the lithographic patterning process comprises:

determining a pre-processed image obtained by removing noise from the image; and identifying the one or more feature characteristics from the pre-processed image.
22. An apparatus according to clause 21, wherein determining the pre-processed image comprises determining an image comprising a gradient magnitude of the image.
23. An apparatus according to any of clauses 21-22, wherein determining the pre-processed image comprises determining a binary image based on the image, the binary image expressing the data in the image in a binary way.
24. An apparatus according to any of clauses 21-23, wherein determining the pre-processed image comprises:

detecting one or more line features in the image and/or the binary image; and

rotating the image and/or the binary image such that at least one of the one or more line features is parallel or perpendicular to the boundary between the first region and the second region.
25. An apparatus according to any of clauses 21-24, wherein identifying the one or more feature characteristics from the pre-processed image comprises applying a Fourier transform to a plurality of portions of the pre-processed image for quantifying a stitching quality at the boundary between the first region and the second region.
26. An apparatus according to clause 25, wherein identifying the one or more feature characteristics from the pre-processed image further comprises determining a duty cycle for the plurality of Fourier-transformed portions, and determining one or more feature characteristics based on the duty cycle for the plurality of portions.
27. An apparatus according to any of clauses 25-26, wherein identifying the one or more feature characteristics from the pre-processed image further comprises determining a phase for the plurality of Fourier-transformed portions, and determining one or more feature characteristics based on the phase for the plurality of portions.
28. An apparatus according to any of clauses 25-27, wherein the plurality of portions comprise a plurality of pixel rows, wherein the rows are aligned to the boundary between the first region and the second region.
29. An apparatus according to clause 23, wherein determining the performance of the lithographic patterning process comprises:

determining a first binary image based on the image;

determining a second binary image based on the binary gradient of the image; and

identifying the one or more feature characteristics based on a combination of the first binary image and the second binary image.
30. An apparatus according to any of clauses 25-29, wherein the one or more feature characteristics comprises overlay.
31. An apparatus according to any of clauses 25-30, wherein identifying the one or more feature characteristics uses a regression model and/or a lookup table.
32. An apparatus according to any of the preceding clauses, wherein determining a performance of the lithographic patterning process further comprises determining a metric for a stitching quality at the boundary between the first region and the second region.
33. An apparatus according to clause 32, wherein the metric represent at least one of a flatness of the stitching around the boundary between the first region and the second region, and the skewness of the stitching around the boundary between the first region and the second region.
34. An apparatus according to any of the preceding clauses, wherein the first region and the second region form part of a same device on the substrate.
35. An apparatus according to any of the preceding clauses, wherein the first region is a first field exposed on the substrate, the second region is a second field exposed on the substrate;

and wherein the boundary comprises a portion of a border of the first field and a border of the second field.
36. An apparatus according to clause 23, wherein determining the performance comprises determining a stitching error between the first field and the second field.
37. An apparatus according to any of the preceding clauses, wherein the received image comprises the substrate in between exposure of subsequent layers on the substrate.
38. An apparatus according to any of the preceding clauses, wherein the received image comprises a boundary between the first and second regions extending in at least one direction.
39. An apparatus according to any of the preceding clauses, wherein the processor is configured to receive a plurality of images, and determine the quality of the patterning process based on the plurality of images.
40. An apparatus according to clause 39, wherein the plurality of images comprise a first image comprising a boundary between the first and second regions in a first direction, and a second image comprising a boundary between the first region and a further region in a second direction, and wherein the first direction and the second direction are not parallel to each other.
41. An apparatus according to clause 40, wherein the first direction and the second direction are substantially perpendicular to each other.
42. An apparatus according to any of clause 40-41, wherein the one or more processors are further configured to determine a performance of one or more process characteristics for the first image, and to determine one or more process characteristics for the second image; and

combine the one or more process characteristics of the first and second images to determine a performance of the patterning process.
43. An apparatus according to any of clauses 39-42, wherein the plurality of images depict a plurality of separate positions on the substrate.
44. An apparatus according to clause 43, wherein one or more process characteristics are determined for the separate positions on the substrate.
45. An apparatus according to any of the preceding clauses, wherein the one or more processors are further configured to determine one or more corrections to the patterning process based on the performance of the lithographic patterning process.
46. An apparatus according to clause 45, wherein the one or more processors are further configured to update the lithographic patterning process with the one or more corrections.
47. An apparatus according to clause 46, wherein updating the lithographic patterning process comprises updating at least one of one or more exposure settings of a lithographic apparatus, and a reticle design.
48. An apparatus according to any of the preceding clauses, wherein the lithographic patterning process is configured to pattern a substrate using a reticle and electromagnetic radiation.
49. An apparatus according to any of the preceding clauses, wherein the one or more processors are further configured to control a metrology apparatus to obtain the image.
50. An apparatus according to clause 49, wherein controlling a metrology apparatus to obtain the image comprises guiding the metrology apparatus is based on previously determined one or more feature characteristics.
51. An apparatus according to clause 48, wherein the metrology apparatus comprises an electron beam imager.
52. A method for determining a performance of a lithographic patterning process, the method comprising:

receiving an image of a portion of a substrate, the portion of the substrate comprising a first region comprising first features associated with a first lithographic exposure of the substrate at a first time, and a second region comprising second features associated with a second lithographic exposure of the substrate at a second time, wherein the first features and the second features form a single feature extending along at least part of the first region and at least part of the second region, and wherein the first and second regions do not overlap; and

determining the performance of the lithographic patterning process based on one or more feature characteristics of the first and/or second exposed features associated with a boundary between the first region and the second region.
53. A method according to clause 52, wherein the boundary comprises a portion of an outer border of the first region and a portion of an outer border of the second region.
54. A method according to any of clauses 52 to 53, wherein the first features and the second features comprise at least one of product features, and dummy features having one or more dimensions the same as the product features.
55. A method according to any of clauses 52 to 54, wherein the substrate is wafer.
56. A method according to any of clauses 52 to 55, wherein the one or more feature characteristics comprises a distance metric comprising:

a distance between one or more axes of symmetry of the first features and one or more axes of symmetry of the second features; and/or

a physical distance between the first features and the second features.
57. A method according to clause 55, wherein the one or more feature characteristics comprise a narrowing or a thickening of the single feature at or proximal to the boundary.
58. A method according to any of clauses 52 to 57, wherein the first features and the second features form part of a patterned layer of photoresist or a layer of material after being patterned by an etching process.
59. A method according to any of clauses 52 to 58, wherein determining the performance comprises analysing the image to determine one or more feature characteristics of the first and/or second features associated with the boundary between the first region and the second region.
60. A method according to clause 59, wherein determining the performance comprises performing a comparison of the first and/or second features of the image to a standard for the first and/or second features.
61. A method according to clause 59 or 60, wherein determining the performance further comprises determining a performance of one or more lithographic patterning process characteristics, based on the determined one or more feature characteristics.
62. A method according to clause 61, wherein the one or more feature characteristics comprise a spatial dimension of the first and/or second features.
63. A method according to clause 61 or 62, wherein the one or more process characteristics comprise one or more of magnification, translation, and/or a higher order deformation error associated with the patterning of the first region and/or the second region.
64. A method according to any of clauses 60 to 63, wherein the performance of the one or more process characteristics is determined at least in part using a model taking as input at least one of the one or more feature characteristics.
65. A method according to clause 64, wherein the model comprises a machine learning model.
66. A method according to clause 65, wherein the model comprises a neural network.
67. A method according to clause 66, wherein the model comprises vision technology.
68. A method according to any of clauses 65-66, wherein the model is configured to be trained on a training set of images of a portion of the substrate comprising first and second features, wherein the first and/or second features of the training set images have one or more known feature characteristics linked to a known performance of the lithographic patterning process.
69. An apparatus according to clause 68, wherein each training set image comprises a portion of a training substrate comprising first features associated with a first lithographic exposure of the training substrate at a first time, and second features associated with a second lithographic exposure of the training substrate at a second time.
70. An apparatus according to any of clauses 68-69, wherein the known feature characteristics and performance of the lithographic patterning process are at least partially based on one or more measurements of one or more feature characteristics of the first and/or second features.
71. An apparatus according to any of clauses 68-70, wherein the known performance of the lithographic patterning process comprises a known stitching error.
72. A method according to any of clauses 52-71, wherein the first region and the second region form part of a same device on the substrate.
73. A method according to any of clauses 52 to 72, wherein the first region is a first field exposed on the substrate, the second region is a second field exposed on the substrate;

and wherein the boundary comprises a portion of a border of the first field and a border of the second field.
74. A method according to clause 73, wherein determining the performance comprises determining a stitching error between the first field and the second field.
75. A method according to any of clauses 52 to 74, wherein the received image comprises the substrate in between exposure of subsequent layers on the substrate.
76. A method according to any of clauses 52 to 75, wherein the received image comprises a boundary between the first and second regions extending in at least one direction.
77. A method according to any of clauses 52 to 76, wherein the method further comprises receiving a plurality of images, and determining the quality of the patterning process based on the plurality of images.
78. A method according to clause 77, wherein the plurality of images comprise a first image comprising a boundary between the first and second regions in a first direction, and a second image comprising a boundary between the first region and a further region in a second direction, and wherein the first direction and the second direction are not parallel to each other.
79. A method according to clause 78, wherein the first direction and the second direction are substantially perpendicular to each other.
80. A method according to any of clause 78 to 79, wherein the method further comprises:

determining a performance of one or more process characteristics for the first image, and determining one or more process characteristics for the second image; and

combining the one or more process characteristics of the first and second images to determine a performance of the patterning process.
81. A method according to any of clauses 77 to 80, wherein the plurality of images depict a plurality of separate positions on the substrate.
82. A method according to clause 81, wherein one or more process characteristics are determined for the separate positions on the substrate.
83. A method according to any of clauses 52 to 82, wherein the method further comprises determining one or more corrections to the patterning process based on the performance of the lithographic patterning process.
84. A method according to clause 83, wherein the method further comprises updating the lithographic patterning process with the one or more corrections.
85. A method according to clause 84, wherein updating the lithographic patterning process comprises updating at least one of one or more exposure settings of a lithographic apparatus, and a reticle design.
86. A method according to any of clauses 52 to 85, wherein the lithographic patterning process is configured to pattern a substrate using a reticle and electromagnetic radiation.
87. A method according to any of clauses 52 to 86, wherein the method further comprises controlling a metrology apparatus to obtain the image.
88. A method according to clause 87, wherein controlling a metrology apparatus to obtain the image comprises guiding the metrology apparatus is based on previously determined one or more feature characteristics.
89. A method according to clause 87, wherein the metrology apparatus comprises an electron beam imager.
90. a method for characterizing a patterning process, the method comprising:

obtaining a plurality of values of stitching errors made along one or more boundaries between at least two patterned adjacent fields or sub-fields on a substrate; and

fitting a distortion model to the plurality of values to obtain a fingerprint representing deformation of a field or sub-field out of said at least two patterned adjacent fields or sub-fields.
91. The method of clause 90, wherein the stitching errors are translation errors between first parts of features comprised within a first field or sub-field out of said at least two patterned adjacent fields or sub-fields and second parts of the features comprised within a second field or sub-field out of said at least two adjacent patterned fields or sub-fields.
92. The method of clause 90 or 91, wherein the distortion model comprised distortion model parameters associated with 2D polynomial base functions.
93. The method of clause 90 or 91, wherein the distortion model comprised distortion model parameters associated with spline functions.
94. The method of any of clauses 90 to 93, wherein the plurality of values of stitching errors include first values of stitching errors made along a first boundary between a first and a second adjacent field or sub-field and second values of stitching errors made along a second boundary between the first field or sub-field and a third adjacent field or sub-field, wherein the orientation of the first and second boundary is different.
95. The method of any of clauses 90 to 94, wherein the plurality of values of the stitching errors are associated with at least two different types of features and the distortion model is fitted to a subset of the plurality of values associated with one or more stitching error critical types of features.
96. The method of clause 95, further comprising assigning a weight factor to distortion model parameters associated with the distortion model based on a measure of criticality of the stitching error critical types of feature.
97. The method of any of clauses 90 to 96, wherein the obtaining of the plurality of values comprises weighted averaging of stitching errors associated with different types of features.
98. The method of clause 97, wherein the weighting is based on on a measure of criticality of the type of feature.
99. The method of clause 98, wherein the weighting is the same for each type of feature.
100. The method of any of clauses 90 to 99, further comprising configuring a lithographic apparatus using parameters values associated with the fitted distortion model.
101. The method of any of clauses 90 to 100, further comprising:

obtaining intra-field and/or inter-field deformation data; and

performing one or more of: verifying consistency of the plurality of values of the stitching errors with the intra-field and/or inter-field data; combining the fingerprint with the intra-field and/or inter-field data to obtain an augmented fingerprint; de-correct the fingerprint to isolate one or more contributors to the fingerprint.
102. The method of any of clauses 90 to 101, further comprising manufacturing, designing or modifying a patterning device used in the patterning process based on the fingerprint or a systematic component isolated from the fingerprint.
103. The method of clause 102, wherein the modification of the patterning device is based on local exposure of a substrate of the patterning device to laser pulses, wherein the length of the laser pulses are in the femtosecond range and cause local modification of the density of the material of the substrate of the patterning device.
104. The method of clause 94, wherein the fitting of the distortion model is performed at least partially in separate steps, comprising at least a first step of fitting exclusively the distortion model to the first values of stitching errors and a second step of fitting the distortion model exclusively to the second values of stitching errors.
105. The method of clause 74, wherein the stitching error comprises a plurality of values of stitching errors made along one or more boundaries between at least two patterned adjacent fields or sub-fields on a substrate; and the method further comprises fitting a distortion model to the plurality of values to obtain a fingerprint representing deformation of a field or sub-field out of said at least two patterned adjacent fields or sub-fields.
106. The method of clause 105, wherein the stitching errors are translation errors between first parts of features comprised within a first field or sub-field out of said at least two patterned adjacent fields or sub-fields and second parts of the features comprised within a second field or sub-field out of said at least two adjacent patterned fields or sub-fields.
107. The method of clause 105 or 106, wherein the distortion model comprised distortion model parameters associated with 2D polynomial base functions.
108. The method of clause 105 or 106, wherein the distortion model comprised distortion model parameters associated with spline functions.
109. The method of any of clauses 105 to 108, wherein the plurality of values of stitching errors include first values of stitching errors made along a first boundary between a first and a second adjacent field or sub-field and second values of stitching errors made along a second boundary between the first field or sub-field and a third adjacent field or sub-field, wherein the orientation of the first and second boundary is different.
110. The method of any of clauses 105 to 109, wherein the plurality of values of the stitching errors are associated with at least two different types of features and the distortion model is fitted to a subset of the plurality of values associated with one or more stitching error critical types of features.
111. The method of clause 110, further comprising assigning a weight factor to distortion model parameters associated with the distortion model based on a measure of criticality of the stitching error critical types of feature.
112. The method of any of clauses 105 to 111, wherein the obtaining of the plurality of values comprises weighted averaging of stitching errors associated with different types of features.
113. The method of clause 112, wherein the weighting is based on on a measure of criticality of the type of feature.
114. The method of clause 113, wherein the weighting is the same for each type of feature.
115. The method of any of clauses 105 to 114, further comprising configuring a lithographic apparatus using parameters values associated with the fitted distortion model.
116. The method of any of clauses 105 to 115, further comprising:

obtaining intra-field and/or inter-field deformation data; and

performing one or more of: verifying consistency of the plurality of values of the stitching errors with the intra-field and/or inter-field data; combining the fingerprint with the intra-field and/or inter-field data to obtain an augmented fingerprint; de-correct the fingerprint to isolate one or more contributors to the fingerprint.
117. The method of any of clauses 105 to 116, further comprising manufacturing, designing or modifying a patterning device used in the patterning process based on the fingerprint or a systematic component isolated from the fingerprint.
118. The method of clause 117, wherein the modification of the patterning device is based on local exposure of a substrate of the patterning device to laser pulses, wherein the length of the laser pulses are in the femtosecond range and cause local modification of the density of the material of the substrate of the patterning device.
119. The method of clause 109, wherein the fitting of the distortion model is performed at least partially in separate steps, comprising at least a first step of fitting exclusively the distortion model to the first values of stitching errors and a second step of fitting the distortion model exclusively to the second values of stitching errors.
120. A computer program product comprising computer readable instruction to perform, when executed on a suitable apparatus the method of any of clauses 52 to 119.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of interest of the structure on the substrate may relate to defects in the structure, the absence of a specific part of the structure, or the presence of an unwanted structure on the substrate or on the wafer.

1.-20. (canceled)

21. A method for characterizing a patterning process, the method comprising:
obtaining a plurality of values of stitching errors made along one or more boundaries between at least two patterned adjacent fields or sub-fields on a substrate; and
fitting, using a hardware computer system, a distortion model to the plurality of values to obtain a fingerprint representing deformation of a field or sub-field out of the at least two patterned adjacent fields or sub-fields.

22. The method of claim 21, wherein the stitching errors are translation errors between first parts of features comprised within a first field or sub-field out of the at least two patterned adjacent fields or sub-fields and second parts of the features comprised within a second field or sub-field out of the at least two adjacent patterned fields or sub-fields.

23. The method of claim 21, wherein the distortion model comprises distortion model parameters associated with 2D polynomial base functions or spline functions.

24. The method of claim 21, wherein the plurality of values of stitching errors include first values of stitching errors made along a first boundary between a first and a second adjacent field or sub-field and second values of stitching errors made along a second boundary between the first field or sub-field and a third adjacent field or sub-field, wherein the orientation of the first and second boundary is different.

25. The method of claim 24, wherein the fitting of the distortion model is performed at least partially in separate steps, comprising at least a first step of fitting exclusively the distortion model to the first values of stitching errors and a second step of fitting the distortion model exclusively to the second values of stitching errors.

26. The method of claim 21, wherein the plurality of values of the stitching errors are associated with at least two different types of features and the distortion model is fitted to a subset of the plurality of values associated with one or more stitching error critical types of features.

27. The method of claim 26, further comprising assigning a weight factor to distortion model parameters associated with the distortion model based on a measure of criticality of the stitching error critical types of feature.

28. The method of claim 21, wherein the obtaining of the plurality of values comprises weighted averaging of stitching errors associated with different types of features.

29. The method of claim 28, wherein the weighting is based on a measure of criticality of the type of feature.

30. The method of claim 21, further comprising configuring a lithographic apparatus using a parameter value associated with the fitted distortion model.

31. The method of claim 21, further comprising:
obtaining intra-field and/or inter-field deformation data; and
performing one or more selected from:
verifying consistency of the plurality of values of the stitching errors with the intra-field and/or inter-field data,
combining the fingerprint with the intra-field and/or inter-field data to obtain an augmented fingerprint, and/or
de-correct the fingerprint to isolate one or more contributors to the fingerprint.

32. The method of claim 21, further comprising manufacturing, designing or modifying a patterning device for use in the patterning process based on the fingerprint or a systematic component isolated from the fingerprint.

33. The method of claim 32, comprising modifying the patterning device, wherein the modification of the patterning device is based on local exposure of a substrate of the patterning device to laser pulses, wherein the length of the laser pulses are in the femtosecond range and cause local modification of a density of the material of the substrate of the patterning device.

34. A non-transitory computer program product comprising computer-readable instructions therein, the instructions, when executed by a computer system, configured to cause the computer system to at least:
obtain a plurality of values of stitching errors made along one or more boundaries between at least two patterned adjacent fields or sub-fields on a substrate; and
fit a distortion model to the plurality of values to obtain a fingerprint representing deformation of a field or sub-field out of the at least two patterned adjacent fields or sub-fields.

35. The computer program product of claim 34, wherein the stitching errors are translation errors between first parts of features comprised within a first field or sub-field out of the at least two patterned adjacent fields or sub-fields and second parts of the features comprised within a second field or sub-field out of the at least two adjacent patterned fields or sub-fields.

36. The computer program product of claim 34, wherein the distortion model comprises distortion model parameters associated with 2D polynomial base functions or spline functions.

37. The computer program product of claim 34, wherein the plurality of values of stitching errors include first values of stitching errors made along a first boundary between a first and a second adjacent field or sub-field and second values of stitching errors made along a second boundary between the first field or sub-field and a third adjacent field or sub-field, wherein the orientation of the first and second boundary is different.

38. The computer program product of claim 34, wherein the plurality of values of the stitching errors are associated with at least two different types of features and the distortion model is fitted to a subset of the plurality of values associated with one or more stitching error critical types of features.

39. The computer program product of claim 38, wherein the instructions are further configured to cause the computer system to assign a weight factor to distortion model parameters associated with the distortion model based on a measure of criticality of the stitching error critical types of feature.

40. The computer program product of claim 34, wherein the instructions are further configured to cause the computer system to:
obtain intra-field and/or inter-field deformation data; and
perform one or more selected from:
verification of consistency of the plurality of values of the stitching errors with the intra-field and/or inter-field data,
combination of the fingerprint with the intra-field and/or inter-field data to obtain an augmented fingerprint, and/or
de-correction of the fingerprint to isolate one or more contributors to the fingerprint.
